(19) United States
(12) Patent Application Publication
(10) Pub. No.: US 2026/0304871 A1
(43) Pub. Date: Oct. 1, 2026

(54) SEMICONDUCTOR DEVICE INCLUDING A FIELD EFFECT TRANSISTOR AND METHOD FOR MANUFACTURING THE SAME

(71) Applicant: SAMSUNG ELECTRONICS CO., LTD., Suwon-si (KR)

(72) Inventors: Jinbum KIM, Seoul (KR); Dongmyoung KIM, Suwon-si (KR); Cheol KIM, Hwaseong-si (KR); Dongsuk SHIN, Suwon-si (KR); Woogwan SHIM, Yongin-si (KR); Seung Hun LEE, Hwaseong-si (KR); Soonwook JUNG, Hwaseong-si (KR)

(73) Assignee: SAMSUNG ELECTRONICS CO., LTD., Suwon-si (KR)

(21) Appl. No.: 19/702,022

(22) Filed: Jun. 9, 2026

Related U.S. Application Data
(63) Continuation of application No. 17/718,795, filed on Apr. 12, 2022.

(30) Foreign Application Priority Data
Aug. 18, 2021 (KR) 10-2021-0108968

(51) Int. Cl. H10D 62/17; H10D 62/13; H10D 64/01; H10D 84/01; H10D 84/03

(52) U.S. Cl. CPC H10D 62/235; H10D 62/151; H10D 64/021; H10D 84/0128; H10D 84/013; H10D 84/0147; H10D 84/038

(57) ABSTRACT

A semiconductor device includes: an active pattern disposed on a substrate; a source/drain pattern disposed on the active pattern; a channel pattern connected to the source/drain pattern, wherein the channel pattern includes semiconductor patterns stacked on each other and spaced apart from each other; and a gate electrode disposed on the channel pattern and extending in a first direction, wherein the gate electrode includes: a channel neighboring part adjacent to a first sidewall of a first semiconductor pattern of the stacked semiconductor patterns; and a body part spaced apart from the first semiconductor pattern, wherein the channel neighboring part is disposed between the body part and the first semiconductor pattern, wherein the first sidewall of the first semiconductor pattern has a first width, wherein the channel neighboring part has a second width less than the first width. The body part has a third width greater than the second width.

### CROSS-REFERENCE TO RELATED APPLICATION

This application is a Continuation of U.S. patent application Ser. No. 17/718,795, filed on Apr. 12, 2022, which claims priority under 35 U.S.C. § 119 to Korean Patent Application No. 10-2021-0108968, filed on Aug. 18, 2021, in the Korean Intellectual Property Office, the disclosure of which is incorporated by reference herein in its entirety.

### TECHNICAL FIELD

The present inventive concept relates to a semiconductor device and a method for manufacturing the same, and more particularly, to a semiconductor device including a field effect transistor and a method for manufacturing the same.

### DISCUSSION OF THE RELATED ART

Generally, semiconductor devices may include integrated circuits including metal-oxide-semiconductor field effect transistors (MOSFETs). As sizes and design rules of semiconductor devices have been reduced, MOSFETs have been scaled down. However, operating characteristics of semiconductor devices may be deteriorated by a reduction in size of MOSFETs. Accordingly, various methods for forming semiconductor devices which may have increased performance while overcoming limitations caused by high integration and a reduction in size have been under development.

### SUMMARY

According to an exemplary embodiment of the present inventive concept, a semiconductor device includes: an active pattern disposed on a substrate; a source/drain pattern disposed on the active pattern; a channel pattern connected to the source/drain pattern, wherein the channel pattern includes semiconductor patterns stacked on each other and spaced apart from each other; and a gate electrode disposed on the channel pattern and extending in a first direction, wherein the gate electrode includes: a channel neighboring part adjacent to a first sidewall of a first semiconductor pattern of the stacked semiconductor patterns; and a body part spaced apart from the first semiconductor pattern, wherein the channel neighboring part is disposed between the body part and the first semiconductor pattern, wherein the first sidewall of the first semiconductor pattern has a first width, wherein the channel neighboring part has a second width less than the first width, and wherein the body part has a third width greater than the second width.

According to an exemplary embodiment of the present inventive concept, a semiconductor device includes: an active pattern disposed on a substrate; a source/drain pattern disposed on the active pattern; a channel pattern connected to the source/drain pattern, wherein the channel pattern includes semiconductor patterns stacked on each other and spaced apart from each other; and a gate electrode disposed on the channel pattern and extending in a first direction, wherein the gate electrode includes: a channel neighboring part adjacent to a first sidewall of a first semiconductor pattern of the stacked semiconductor patterns; and a body part spaced apart from the first semiconductor pattern, wherein the channel neighboring part is disposed between the body part and the first semiconductor pattern, wherein the channel neighboring part includes a second sidewall extending diagonally with respect to the first sidewall, wherein the body part includes a third sidewall extending substantially perpendicularly to the first sidewall, and wherein an angle between the first sidewall and the second sidewall ranges from about 30° to about 80°.

According to an exemplary embodiment of the present inventive concept, a method for manufacturing a semiconductor device includes: alternately stacking sacrificial layers and active layers on a substrate; forming a stack pattern on an active pattern by patterning the sacrificial layers and the active layers; forming an etch facilitation layer on the stack pattern; forming a sacrificial semiconductor layer on the etch facilitation layer; forming a sacrificial pattern by etching the sacrificial semiconductor layer; forming a recess by etching the stack pattern at a side of the sacrificial pattern; forming a source/drain pattern in the recess; forming an outer region by removing the sacrificial pattern and the etch facilitation layer; forming inner regions by removing the sacrificial layers exposed by the outer region; and forming a gate electrode in the outer region and the inner regions, wherein the etch facilitation layer is patterned together with the sacrificial semiconductor layer in the etching of the sacrificial semiconductor layer, and wherein an etch rate of the etch facilitation layer is greater than an etch rate of the sacrificial semiconductor layer in the etching of the sacrificial semiconductor layer.

### BRIEF DESCRIPTION OF THE DRAWINGS

FIG. 1 is a plan view illustrating a semiconductor device according to an exemplary embodiment of the present inventive concept.

FIGS. 2A, 2B, 2C and 2D are cross-sectional views taken along lines A-A', B-B', C-C′ and D-D′ of FIG. 1, respectively.

FIG. 3 is an enlarged plan view taken along a line M-M′ of FIG. 2A.

FIG. 4 is an enlarged cross-sectional view of a region ‘N’ of FIG. 2A.

FIGS. 5A, 5B, 6A, 6B, 7A, 7B, 7C, 7D, 8A, 8B, 8C, 8D, 8E, 8F, 9A, 9B, 9C, 9D, 9E, 9F, 10A, 10B, 10C, 10D, 10E, 10F, 11A, 11B, 11C, and 11D are views illustrating a method for manufacturing a semiconductor device according to an exemplary embodiment of the present inventive concept.

FIGS. 12 and 13 are plan views taken along lines M-M′ of FIGS. 9A and 10A, respectively, to illustrate a method for manufacturing a semiconductor device according to a comparative example.

FIG. 14 is a plan view taken along the line M-M′ of FIG. 2A to illustrate a semiconductor device according to an exemplary embodiment of the present inventive concept.

FIGS. 15A, 15B, 15C and 15D are cross-sectional views taken along the lines A-A′, B-B′, C-C′ and D-D′ of FIG. 1, respectively, to illustrate a semiconductor device according to an exemplary embodiment of the present inventive concept.

### DETAILED DESCRIPTION OF THE EMBODIMENTS

It will be understood that the drawings are not to scale and might not precisely reflect the precise structural or performance characteristics of any given exemplary embodiment, and should not be interpreted as defining or limiting the range of values or properties encompassed by exemplary embodiments of the present inventive concept. For example, the relative thicknesses and positioning of molecules, layers, regions and/or structural elements may be reduced or exaggerated for clarity.

Exemplary embodiments of the present inventive concept will be described more fully hereinafter with reference to the accompanying drawings.

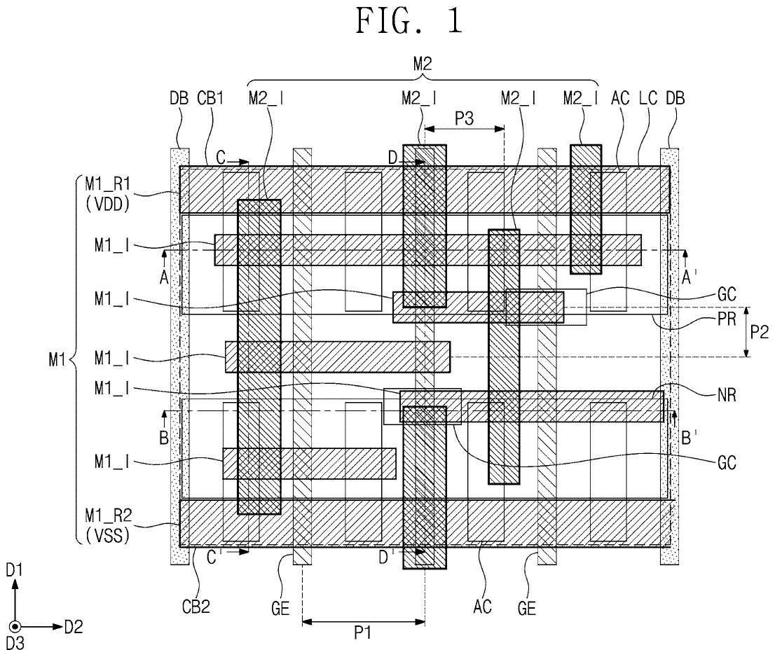

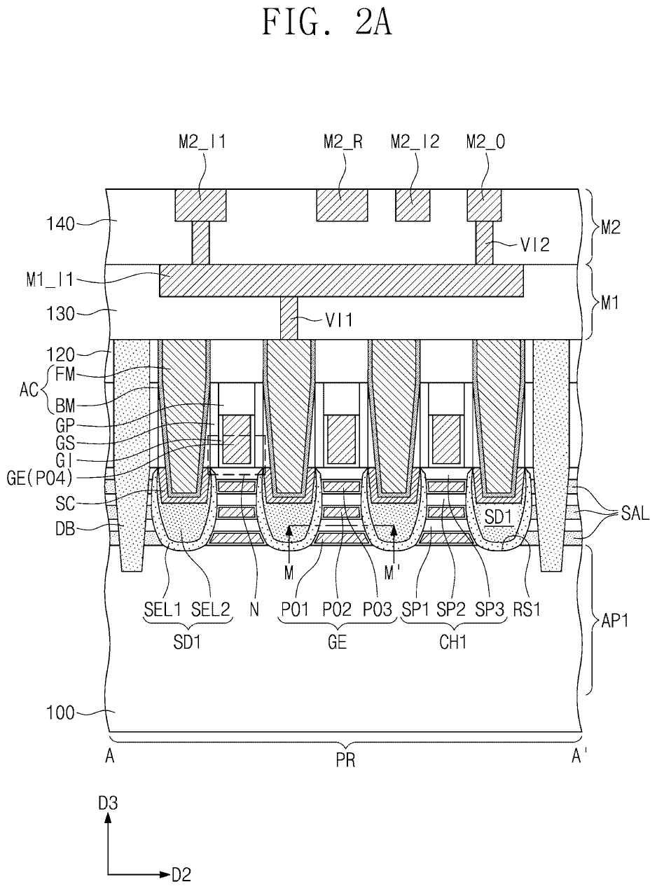

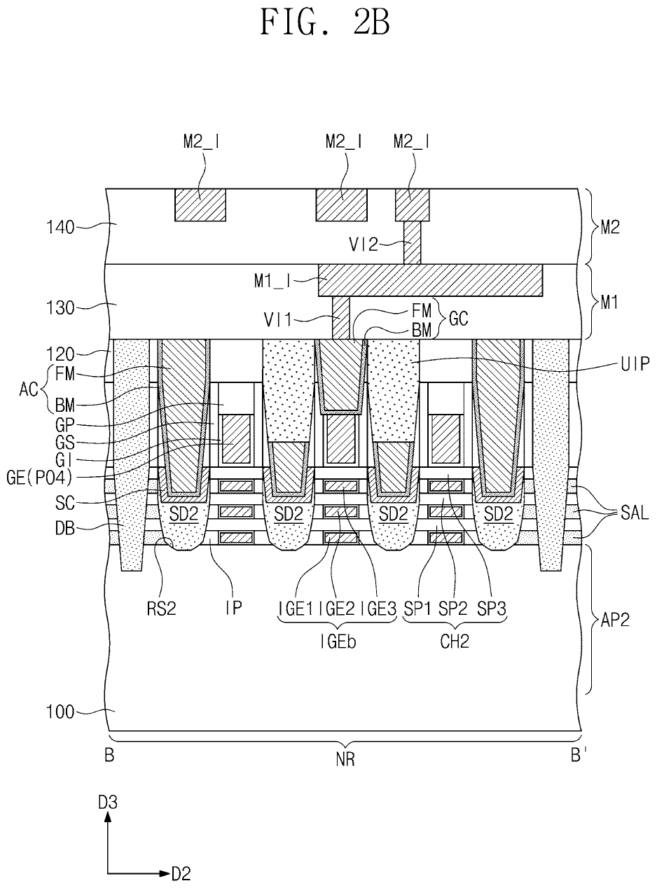

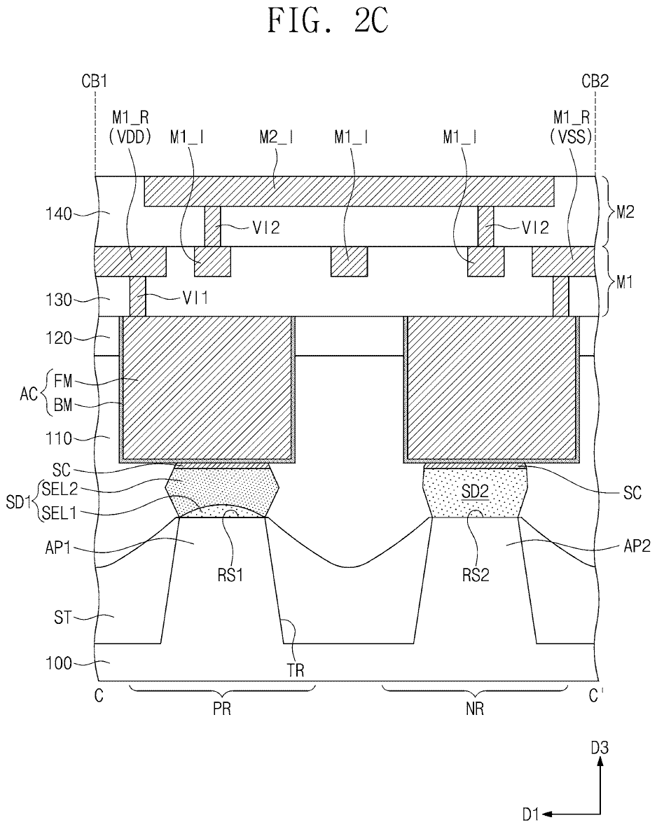

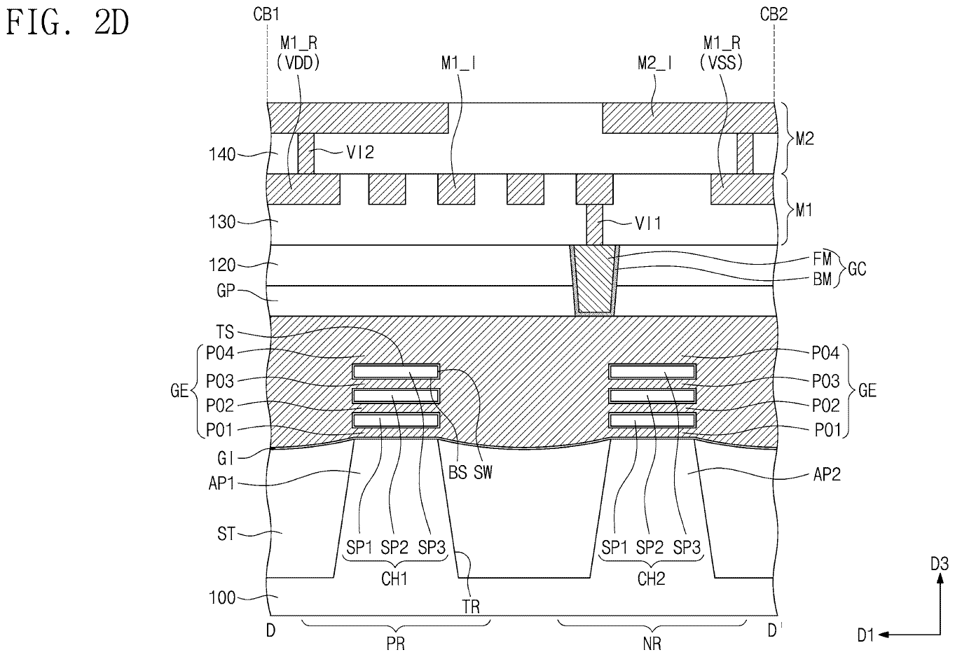

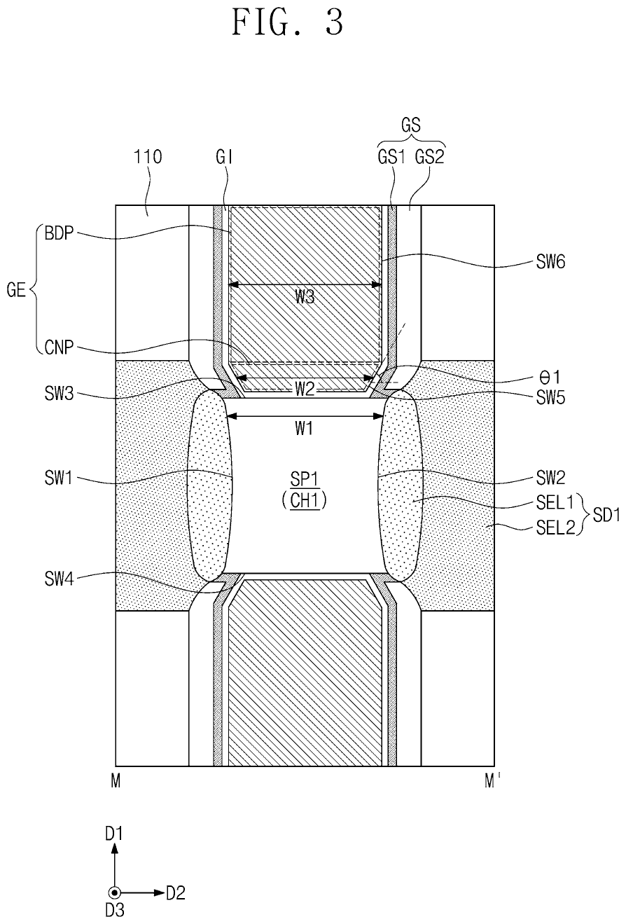

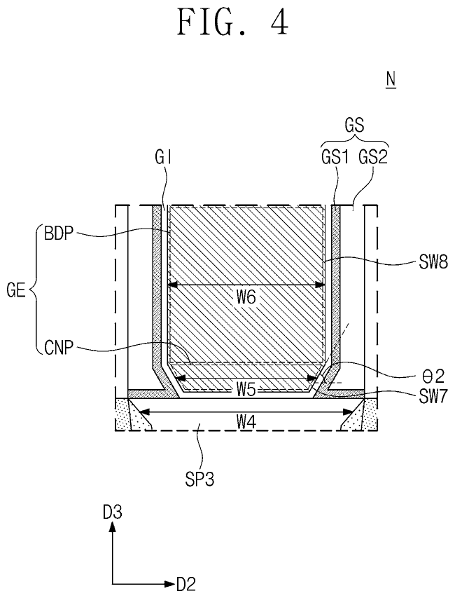

FIG. 1 is a plan view illustrating a semiconductor device according to an exemplary embodiment of the present inventive concept. FIGS. 2A, 2B, 2C and 2D are cross-sectional views taken along lines A-A′, B-B′, C-C′ and D-D′ of FIG. 1, respectively. FIG. 3 is an enlarged plan view taken along a line M-M′ of FIG. 2A. FIG. 4 is an enlarged cross-sectional view of a region ‘N’ of FIG. 2A.

Referring to FIGS. 1 and 2A to 2D, a logic cell LC may be provided on a substrate 100. Logic transistors constituting a logic circuit may be disposed on the logic cell LC. The substrate 100 may be a semiconductor substrate including, for example, silicon, germanium or silicon-germanium, or a compound semiconductor substrate. For example, the substrate 100 may be a silicon substrate. However, the present inventive concept is not limited thereto.

The logic cell LC may include a PMOSFET region PR and an NMOSFET region NR. The PMOSFET region PR and the NMOSFET region NR may be defined by a trench TR formed in the substrate 100. For example, the trench TR may be formed in the substrate 100. In other words, the trench TR may be disposed between the PMOSFET region PR and the NMOSFET region NR. The PMOSFET region PR and the NMOSFET region NR may be spaced apart from each other in a first direction D1 with the trench TR interposed therebetween.

A first active pattern AP1 and a second active pattern AP2 may be provided on the PMOSFET region PR and the NMOSFET region NR of the substrate 100, respectively. The first active pattern AP1 and the second active pattern AP2 may be defined by the trench TR. The first and second active patterns AP1 and AP2 may extend in a second direction D2. Each of the first and second active patterns AP1 and AP2 may be an upper portion of the substrate 100, which protrudes vertically with respect to a lower surface of the substrate 100.

A device isolation layer ST may fill the trench TR. The device isolation layer ST may cover sidewalls of the first and second active patterns AP1 and AP2. For example, the device isolation layer ST may include a silicon oxide layer.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2 and a third semiconductor pattern SP3, which are sequentially stacked. The first to third semiconductor patterns SP1, SP2 and SP3 may be spaced apart from each other in a vertical direction (e.g., a third direction D3). For example, the first channel pattern CH1 and the second channel pattern CH2 may be respectively spaced apart from the first active pattern AP1 and the second active pattern AP2.

Each of the first to third semiconductor patterns SP1, SP2 and SP3 may include, for example, silicon (Si), germanium (Ge), or silicon-germanium (SiGe). For example, each of the first to third semiconductor patterns SP1, SP2 and SP3 may include silicon (Si).

A plurality of first recesses RS1 may be formed on the first active pattern AP1. First source/drain patterns SD1 may be provided in the first recesses RS1, respectively. The first source/drain patterns SD1 may be dopant regions having a first conductivity type (e.g., a p-type). The first channel pattern CH1 may be disposed between a pair of the first source/drain patterns SD1. In other words, the first to third semiconductor patterns SP1, SP2 and SP3 that are stacked sequentially may connect the pair of first source/drain patterns SD1 to each other.

A plurality of second recesses RS2 may be formed on the second active pattern AP2. Second source/drain patterns SD2 may be provided in the second recesses RS2, respectively. The second source/drain patterns SD2 may be dopant regions having a second conductivity type (e.g., an n-type). The second channel pattern CH2 may be disposed between a pair of the second source/drain patterns SD2. In other words, the first to third semiconductor patterns SP1, SP2 and SP3 that are stacked sequentially may connect the pair of second source/drain patterns SD2 to each other.

The first and second source/drain patterns SD1 and SD2 may be epitaxial patterns formed by a selective epitaxial growth process. For example, a top surface of each of the first and second source/drain patterns SD1 and SD2 may be located at substantially the same level as a top surface of the third semiconductor pattern SP3. However, the present inventive concept is not limited thereto. For example, the top surface of each of the first and second source/drain patterns SD1 and SD2 may be higher than the top surface of the third semiconductor pattern SP3.

The first source/drain patterns SD1 may include a semiconductor element (e.g., SiGe) of which a lattice constant is greater than a lattice constant of a semiconductor element of the substrate 100. Thus, the pair of first source/drain patterns SD1 may provide compressive stress to the first channel pattern CH1 therebetween. The second source/drain patterns SD2 may include the same semiconductor element (e.g., Si) as that of the substrate 100.

Each of the first source/drain patterns SD1 may include a first semiconductor layer SEL1 and a second semiconductor layer SEL2 disposed on the first semiconductor layer SEL1. A sectional shape of the first source/drain pattern SD1, which is taken along the second direction D2, will be described with reference to FIG. 2A.

The first semiconductor layer SEL1 may cover an inner surface of the first recess RS1. In an exemplary embodiment of the present inventive concept, a thickness of the first semiconductor layer SEL1 may become progressively less from its lower portion toward its upper portion. For example, a thickness, in the third direction D3, of the first semiconductor layer SEL1 on a bottom surface of the first recess RS1 may be greater than a thickness, in the second direction D2, of the first semiconductor layer SEL1 on an inner sidewall of an upper portion of the first recess RS1. For example, as the first semiconductor layer SEL1 travels from the bottom surface of the first recess RS1 to the side surface of the first recess RS1 toward the top of the first recess RS1, the thickness of the first semiconductor layer SEL1 decreases. The first semiconductor layer SEL1 may have a U-shape along a profile of the inner surface of the first recess RS1.

In an exemplary embodiment of the present inventive concept, the thickness of the first semiconductor layer SEL1 may be substantially constant from its lower portion toward its upper portion. In other words, the first semiconductor layer SEL1 may have a substantially uniform thickness. For example, the thickness, in the third direction D3, of the first semiconductor layer SEL1 disposed on the bottom of the first recess RS1 may be substantially equal to the thickness, in the second direction D2, of the first semiconductor layer SEL1 disposed on the inner sidewall of the upper portion of the first recess RS1.

The second semiconductor layer SEL2 may fill a remaining region of the first recess RS1 that is not occupied by the first semiconductor layer SEL1. A volume of the second semiconductor layer SEL2 may be greater than a volume of the first semiconductor layer SEL1. In other words, a ratio of the volume of the second semiconductor layer SEL2 to a total volume of the first source/drain pattern SD1 may be greater than a ratio of the volume of the first semiconductor layer SEL1 to the total volume of the first source/drain pattern SD1.

Each of the first semiconductor layer SEL1 and the second semiconductor layer SEL2 may include a semiconductor element of which a lattice constant is greater than the lattice constant of the semiconductor element of the substrate 100. For example, when the substrate 100 includes silicon (Si), the first and second semiconductor layers SEL1 and SEL2 may include silicon-germanium (SiGe). A lattice constant of germanium (Ge) may be greater than a lattice constant of silicon (Si).

For example, the first semiconductor layer SEL1 may contain a relatively low concentration of germanium (Ge). In an exemplary embodiment of the present inventive concept, the first semiconductor layer SEL1 may include silicon (Si) except germanium (Ge). A concentration of germanium (Ge) of the first semiconductor layer SEL1 may range from 0 at % to about 10 at %.

The second semiconductor layer SEL2 may contain a relatively high concentration of germanium (Ge). For example, a concentration of germanium (Ge) of the second semiconductor layer SEL2 may range from about 30 at % to about 70 at %. The concentration of germanium (Ge) of the second semiconductor layer SEL2 may increase as a level in the third direction D3 increases. For example, the second semiconductor layer SEL2 adjacent to the first semiconductor layer SEL1 may have a germanium (Ge) concentration of about 40 at %, but an upper portion of the second semiconductor layer SEL2 may have a germanium (Ge) concentration of about 60 at %.

The first and second semiconductor layers SEL1 and SEL2 may include dopants (e.g., boron) capable of allowing the first source/drain pattern SD1 to have the p-type. A concentration (e.g., atomic percent) of the dopants of the second semiconductor layer SEL2 may be greater than a concentration of the dopants of the first semiconductor layer SEL1. In an exemplary embodiment of the present inventive concept, each of the first and second semiconductor layers SEL1 and SEL2 may additionally include other dopants (e.g., at least one of P, As, or C).

The first semiconductor layer SEL1 may prevent a stacking fault between the substrate 100 and the second semiconductor layer SEL2 and between the second semiconductor layer SEL2 and the first to third semiconductor patterns SP1, SP2 and SP3. When the stacking fault occurs, a channel resistance may be increased. The stacking fault may easily occur at the bottom of the first recess RS1. Thus, to prevent the stacking fault, the thickness of the first semiconductor layer SEL1 adjacent to the bottom surface of the first recess RS1 may be relatively large.

The first semiconductor layer SEL1 may protect the second semiconductor layer SEL2 during a process of replacing sacrificial layers SAL with first to third portions PO1, PO2 and PO3 of a gate electrode GE, to be described later. In other words, the first semiconductor layer SEL1 may prevent an etching material for removing the sacrificial layers SAL from permeating into the second semiconductor layer SEL2 to etch it.

Gate electrodes GE may be provided to intersect the first and second active patterns AP1 and AP2 and to extend in the first direction D1. The gate electrodes GE may be arranged in the second direction D2 at a first pitch P1. Each of the gate electrodes GE may vertically overlap with the first and second channel patterns CH1 and CH2.

The gate electrode GE may include a first portion PO1, a second portion PO2, a third portion PO3, and a fourth portion PO4. The first portion PO1 may be disposed between the substrate 100 and the first semiconductor pattern SP1, and the second portion PO2 disposed between the first semiconductor pattern SP1 and the second semiconductor pattern SP2. The third portion PO3 may be disposed between the second semiconductor pattern SP2 and the third semiconductor pattern SP3, and the fourth portion PO4 disposed on the third semiconductor pattern SP3.

Referring again to FIG. 2A, the first to third portions PO1, PO2 and PO3 of the gate electrode GE that are on the PMOSFET region PR may have different widths from each other. For example, a maximum width of the third portion PO3 in the second direction D2 may be greater than a maximum width of the second portion PO2 in the second direction D2. A maximum width of the first portion PO1 in the second direction D2 may be greater than the maximum width of the third portion PO3 in the second direction D2.

In an exemplary embodiment of the present inventive concept, the maximum width of the third portion PO3 in the second direction D2 may be substantially the same as the maximum width of the second portion PO2 in the second direction D2.

In an exemplary embodiment of the present inventive concept, a maximum width of the third portion PO3 in the second direction D2 may be less than a maximum width of the second portion PO2 in the second direction D2.

Referring again to FIG. 2D, the gate electrode GE may be provided on a top surface TS, a bottom surface BS and both sidewalls SW of each of the first to third semiconductor patterns SP1, SP2 and SP3. In other words, a transistor of the logic cell LC according to the present embodiment may be a three-dimensional field effect transistor (e.g., a MBCFET or GAAFET) in which the gate electrode GE three-dimensionally surrounds a channel.

Referring again to FIGS. 1 and 2A to 2D, a pair of gate spacers GS may be disposed on both sidewalls of the fourth portion PO4 of the gate electrode GE, respectively. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110 to be described later. For example, the gate spacers GS may include at least one of SiCN, SiCON, and/or SiN. For certain examples, each of the gate spacers GS may include a multi-layer structure formed of at least two of SiCN, SiCON, and/or SiN.

A gate capping pattern GP may be provided on the gate electrode GE. The gate capping pattern GP may extend along the gate electrode GE in the first direction D1. The gate capping pattern GP may include a material having an etch selectivity with respect to first and second interlayer insulating layers 110 and 120 to be described later. For example, the gate capping pattern GP may include at least one of SiON, SiCN, SiCON, and/or SiN.

A gate insulating layer GI may be disposed between the gate electrode GE and the first channel pattern CH1 and between the gate electrode GE and the second channel pattern CH2. The gate insulating layer GI may cover the top surface TS, the bottom surface BS and both sidewalls SW of each of the first to third semiconductor patterns SP1, SP2 and SP3. The gate insulating layer GI may cover a top surface of the device isolation layer ST under the gate electrode GE (see FIG. 2D).

The gate electrode GE may include, for example, a first metal pattern, and a second metal pattern on the first metal pattern. The first metal pattern may be provided on the gate insulating layer GI and may be adjacent to the first to third semiconductor patterns SP1, SP2 and SP3. The first metal pattern may include a work function metal of adjusting a threshold voltage of a transistor. A desired threshold voltage of the transistor may be obtained by adjusting a thickness and a composition of the first metal pattern. For example, the first to third portions PO1, PO2 and PO3 of the gate electrode GE may be formed of the first metal pattern corresponding to the work function metal.

The first metal pattern may include a metal nitride layer. For example, the first metal pattern may include nitrogen (N) and at least one of titanium (Ti), tantalum (Ta), aluminum (Al), tungsten (W), and/or molybdenum (Mo). As an additional example, the first metal pattern may further include carbon (C). In an exemplary embodiment of the present inventive concept, the first metal pattern may include a plurality of stacked work function metal layers.

The second metal pattern may include a metal having a resistance lower than that of the first metal pattern. For example, the second metal pattern may include at least one of tungsten (W), aluminum (Al), titanium (Ti), and/or tantalum (Ta). For example, the fourth portion PO4 of the gate electrode GE may include the first metal pattern and the second metal pattern disposed on the first metal pattern.

In an exemplary embodiment of the present inventive concept, the gate insulating layer GI may include a silicon oxide layer, a silicon oxynitride layer, and/or a high-k dielectric layer. For example, the gate insulating layer GI may have a structure in which a silicon oxide layer and a high-k dielectric layer are stacked on each other. The high-k dielectric layer may include a high-k dielectric material of which a dielectric constant is higher than that of a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

In an exemplary embodiment of the present inventive concept, the semiconductor device may include a negative capacitance (NC) FET using a negative capacitor. For example, the gate insulating layer GI may include a ferroelectric material layer, which has ferroelectric properties, and a paraelectric material layer, which has paraelectric properties.

The ferroelectric material layer may have a negative capacitance, and the paraelectric material layer may have a positive capacitance. For example, when two or more capacitors are connected in series to each other and a capacitance of each of the capacitors has a positive value, a total capacitance may be reduced to be less than the capacitance of each of the capacitors. In addition, when at least one of capacitances of two or more capacitors connected in series to each other has a negative value, a total capacitance may have a positive value and may be greater than an absolute value of the capacitance of each of the capacitors.

When the ferroelectric material layer having the negative capacitance is connected in series to the paraelectric material layer having the positive capacitance, a total capacitance value of the ferroelectric and paraelectric material layers connected in series to each other may increase. The transistor including the ferroelectric material layer may have a subthreshold swing (SS) less than about 60 mV/decade at room temperature by using the increase in the total capacitance value.

The ferroelectric material layer may have the ferroelectric properties. For example, the ferroelectric material layer may include at least one of hafnium oxide, hafnium zirconium oxide, barium strontium titanium oxide, barium titanium oxide, and/or lead zirconium titanium oxide. Here, for example, the hafnium zirconium oxide may be a material formed by doping hafnium oxide with zirconium (Zr). For another example, the hafnium zirconium oxide may be a compound of hafnium (Hf), zirconium (Zr), and oxygen (O).

The ferroelectric material layer may further include dopants doped therein. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). A kind of the dopants included in the ferroelectric material layer may be changed depending on a kind of the ferroelectric material included in the ferroelectric material layer.

When the ferroelectric material layer includes hafnium oxide, the dopants included in the ferroelectric material layer may include at least one of, for example, gadolinium (Gd), silicon (Si), zirconium (Zr), aluminum (Al), and/or yttrium (Y).

When the dopants are aluminum (Al), the ferroelectric material layer may include aluminum ranging from about 3 at % (atomic %) to about 8 at %. Here, a ratio of the dopants may be a ratio of the amount of aluminum to a sum of the amounts of hafnium and aluminum.

When the dopants are silicon (Si), the ferroelectric material layer may include silicon ranging from about 2 at % to about 10 at %. When the dopants are yttrium (Y), the ferroelectric material layer may include yttrium ranging from about 2 at % to about 10 at %. When the dopants are gadolinium (Gd), the ferroelectric material layer may include gadolinium ranging from about 1 at % to about 7 at %. When the dopants are zirconium (Zr), the ferroelectric material layer may include zirconium ranging from about 50 at % to about 80 at %.

The paraelectric material layer may have the paraelectric properties. For example, the paraelectric material layer may include at least one of silicon oxide and/or a metal oxide having a high-k dielectric constant. For example, the metal oxide included in the paraelectric material layer may include at least one of, but is not limited to, hafnium oxide, zirconium oxide, and/or aluminum oxide.

The ferroelectric material layer and the paraelectric material layer may include the same material as each other. The ferroelectric material layer may have the ferroelectric properties, but the paraelectric material layer might not have the ferroelectric properties. For example, when the ferroelectric material layer and the paraelectric material layer include hafnium oxide, a crystal structure of hafnium oxide included in the ferroelectric material layer may be different from a crystal structure of hafnium oxide included in the paraelectric material layer.

The ferroelectric material layer may have a thickness showing the ferroelectric properties. For example, the thickness of the ferroelectric material layer may range from about 0.5 nm to about 10 nm, but the present inventive concept is not limited thereto. A critical thickness showing the ferroelectric properties may be changed depending on a kind of a ferroelectric material, and thus the thickness of the ferroelectric material layer may be changed depending on a kind of the ferroelectric material included therein.

For example, the gate insulating layer GI may include a single ferroelectric material layer. For another example, the gate insulating layer GI may include a plurality of the ferroelectric material layers spaced apart from each other. For example, the gate insulating layer GI may have a stack structure in which the ferroelectric material layers and the paraelectric material layers are alternately stacked on each other.

Referring again to FIG. 2B, inner spacers IP may be provided on the NMOSFET region NR. The inner spacers IP may be disposed between the second source/drain pattern SD2 and each of the first to third portions PO1, PO2 and PO3 of the gate electrode GE, respectively. For example, the inner spacers IP may be in direct contact with the second source/drain pattern SD2. Each of the first to third portions PO1, PO2 and PO3 of the gate electrode GE may be spaced apart from the second source/drain pattern SD2 by the inner spacer IP.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 covering the gate capping pattern GP may be disposed on the first interlayer insulating layer 110. For example, the top surface of the first interlayer insulating layer 110 may contact the lower surface of the second interlayer insulating layer 120. For example, each of the first and second interlayer insulating layers 110 and 120 may include a silicon oxide layer.

A pair of isolation structures DB opposite to each other in the second direction D2 may be provided at both sides of the logic cell LC, respectively. The isolation structure DB may extend in the first direction D1 in parallel to the gate electrode GE. A pitch between the isolation structure DB and the gate electrode GE adjacent thereto may be equal to the first pitch P1.

The isolation structure DB may penetrate the first and second interlayer insulating layers 110 and 120 and may extend into the first and second active patterns AP1 and AP2. For example, an upper surface of the isolation structure DP and the upper surface of the second interlayer insulating layer 120 may be coplanar. The isolation structure DB may penetrate an upper portion of each of the first and second active patterns AP1 and AP2. The isolation structure DB may isolate the PMOSFET and NMOSFET regions PR and NR of the logic cell LC from PMOSFET and NMOSFET regions of an adjacent logic cell.

Active contacts AC may penetrate the first and second interlayer insulating layers 110 and 120 and may be electrically connected to the first and second source/drain patterns SD1 and SD2. A pair of the active contacts AC may be provided at both sides of the gate electrode GE, respectively. The active contact AC may have a bar shape or a polygonal shape (e.g., a rectangular shape) extending in the first direction D1 when viewed in a plan view.

The active contact AC may be a self-aligned contact. In other words, the active contact AC may be formed to be self-aligned with the gate capping pattern GP and the gate spacer GS. For example, the active contact AC may cover at least a portion of a sidewall of the gate spacer GS. The active contact AC may cover at least a portion of the top surface of the gate capping pattern GP.

Silicide patterns SC may be disposed between each of some of the active contacts AC and the first source/drain pattern SD1 and between each of the others (e.g., remaining) of the active contacts AC and the second source/drain pattern SD2, respectively. The active contacts AC may be electrically connected to the source/drain patterns SD1 and SD2 through the silicide patterns SC. For example, the silicide pattern SC may include a metal silicide and may include at least one of, for example, titanium silicide, tantalum silicide, tungsten silicide, nickel silicide, and/or cobalt silicide.

A gate contact GC may penetrate the second interlayer insulating layer 120 and the gate capping pattern GP and may be electrically connected to the gate electrode GE. In an exemplary embodiment of the present inventive concept, referring to FIG. 2B, an upper portion of each of the active contacts AC adjacent to the gate contact GC may be filled with an upper insulating pattern UIP. Thus, it is possible to prevent a process defect (e.g., a short between the gate contact GC and the active contact AC adjacent thereto).

Each of the active contact AC and the gate contact GC may include a conductive pattern FM and a barrier pattern BM at least partially surrounding the conductive pattern FM. For example, the conductive pattern FM may include at least one metal of aluminum, copper, tungsten, molybdenum, and/or cobalt. The barrier pattern BM may cover sidewalls and a bottom surface of the conductive pattern FM. For example, the barrier pattern BM may include a metal layer/a metal nitride layer. For example, the metal layer may include at least one of titanium, tantalum, tungsten, nickel, cobalt, and/or platinum. For example, the metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and/or a platinum nitride (PTN) layer.

A first metal layer M1 may be provided in a third interlayer insulating layer 130 disposed on the second interlayer insulating layer 120. The first metal layer M1 may include a first power interconnection line M1_R1, a second power interconnection line M1_R2, and lower interconnection lines M1_I.

Each of the first power interconnection line M1_R1 and the second power interconnection line M1_R2 may intersect the logic cell LC and may extend in the second direction D2. For example, a first cell boundary CB1 extending in the second direction D2 may be defined in the logic cell LC. In the logic cell LC, a second cell boundary CB2 may be opposite the first cell boundary CB1. The first power interconnection line M1_R1 may be disposed on the first cell boundary CB1. The first power interconnection line M1_R1 may extend along the first cell boundary CB1 in the second direction D2. The second power interconnection line M1_R2 may be disposed on the second cell boundary CB2. The second power interconnection line M1_R2 may extend along the second cell boundary CB2 in the second direction D2.

The lower interconnection lines M1_I may be disposed between the first and second power interconnection lines M1_R1 and M1_R2. Each of the lower interconnection lines M1_I may have a line shape, bar shape, or a polygonal shape extending in the second direction D2. For example, each of the lower interconnection lines M1_I may have a rectangular shape. The lower interconnection lines M1_I may be arranged in the first direction D1 at a second pitch P2. For example, the second pitch P2 may be less than the first pitch P1.

The first metal layer M1 may further include lower vias VI1. The lower vias VI1 may be provided under the interconnection lines M1_R1, M1_R2 and M1_I of the first metal layer M1. Some of the lower vias VI1 may be disposed between the active contacts AC and corresponding ones of the interconnection lines M1_R1, M1_R2 and M1_I of the first metal layer M1. The remaining lower vias VI1 may be disposed between the gate contacts GC and corresponding ones of the interconnection lines M1_R1, M1_R2 and M1_I of the first metal layer M1.

The interconnection lines M1_R1, M1_R2 and M1_I of the first metal layer M1 may be formed by a process different from a process of forming the lower vias VI1 thereunder. In other words, the interconnection lines M1_R1, M1_R2 and M1_I of the first metal layer M1 may be formed by a single damascene process, and the lower vias VI1 of the first metal layer M1 may be formed by another single damascene process. The semiconductor device according to the present embodiment may be formed using processes less than about 20 nm.

A second metal layer M2 may be provided in a fourth interlayer insulating layer 140 disposed on the third interlayer insulating layer 130. The second metal layer M2 may include upper interconnection lines M2_I. Each of the upper interconnection lines M2_I of the second metal layer M2 may have a line shape, bar shape, or a polygonal shape extending in the first direction D1. For example, each of the upper interconnection lines M2_I of the second metal layer M2 may have a rectangular shape. In other words, the upper interconnection lines M2_I may extend in the first direction D1 in parallel to each other. The upper interconnection lines M2_I may be parallel to the gate electrodes GE when viewed in a plan view. The upper interconnection lines M2_I may be arranged in the second direction D2 at a third pitch P3. The third pitch P3 may be less than the first pitch P1. The third pitch P3 may be greater than the second pitch P2.

The second metal layer M2 may further include upper vias VI2. The upper vias VI2 may be provided under the upper interconnection lines M2_I. The upper vias VI2 may be disposed between the interconnection lines M1_R1, M1_R2 and M1_I of the first metal layer M1 and the upper interconnection lines M2_I of the second metal layer M2.

The upper interconnection line M2_I and the upper via VI2 thereunder of the second metal layer M2 may be formed as one single body by the same process. In other words, the upper interconnection line M2_I and the upper via VI2 of the second metal layer M2 may be formed together by a dual damascene process.

The interconnection lines of the first metal layer M1 and the interconnection lines of the second metal layer M2 may include the same conductive material or different conductive materials. For example, the interconnection lines of the first metal layer M1 and the interconnection lines of the second metal layer M2 may include at least one of aluminum, copper, tungsten, molybdenum, and/or cobalt. Metal layers (e.g., M3, M4, M5, etc.) may be additionally stacked on the fourth interlayer insulating layer 140. Each of the stacked metal layers may include routing interconnection lines.

Hereinafter, the first semiconductor pattern SP1 on the PMOSFET region PR and the gate electrode GE adjacent thereto will be described in more detail with reference to FIG. 3. More particularly, FIG. 3 may be a plan view of the semiconductor device at a level of the first semiconductor pattern SP1, which is obtained by planarizing the semiconductor device to the first semiconductor pattern SP1 of the first channel pattern CH1.

The first source/drain patterns SD1 may be provided at both sides of the first semiconductor pattern SP1, respectively. The first semiconductor pattern SP1 may include a first sidewall SW1 and a second sidewall SW2, which are opposite to each other in the second direction D2. The first semiconductor layer SEL1 may cover the first and second sidewalls SW1 and SW2 of the semiconductor pattern SP1. For example, each of the first and second sidewalls SW1 and SW2 may be in direct contact with the first semiconductor layer SEL1 of the first source/drain pattern SD1. The first semiconductor pattern SP1 may connect the first source/drain patterns SD1 to each other.

The first semiconductor pattern SP1 may further include a third sidewall SW3 and a fourth sidewall SW4, which are opposite to each other in the first direction D1. The gate electrode GE may be provided on the third and fourth sidewalls SW3 and SW4.

The gate electrode GE may face the third and fourth sidewalls SW3 and SW4 with the gate insulating layer GI interposed therebetween. For example, the gate insulating layer GI may be disposed between the third sidewall SW3 and gate electrode GE, and may be disposed between the fourth sidewall SW4 and the gate electrode GE. For example, the gate electrode GE may include a body part BDP and a channel neighboring part CNP adjacent to the third sidewall SW3 of the first semiconductor pattern SP1. The body part BDP may be spaced apart from the first semiconductor pattern SP1 in the first direction D1 with the channel neighboring part CNP interposed therebetween. The body part BDP may be a line portion of the gate electrode GE, which extends in the first direction D1.

The channel neighboring part CNP may be a portion of the gate electrode GE adjacent to the first channel pattern CH1 (e.g., the first semiconductor pattern SP1). For example, the channel neighboring part CNP may be aligned with the first channel pattern CH1. The channel neighboring part CNP may have a varying width.

The third sidewall SW3 of the first semiconductor pattern SP1 may have a first width W1 in the second direction D2. The channel neighboring part CNP may have a second width W2 in the second direction D2. The second width W2 may be less than the first width W1. The second width W2 may increase toward a direction (e.g., the first direction D1) away from the first semiconductor pattern SP1.

The body part BDP may have a third width W3 corresponding to a uniform line width. The third width W3 may be greater than the second width W2. In an exemplary embodiment of the present inventive concept, the third width W3 may be less than the first width W1. In addition, in an exemplary embodiment of the present inventive concept, the third width W3 may be equal to or greater than the first width W1.

The channel neighboring part CNP may have a fifth sidewall SW5 extending diagonally (e.g., a direction between the first direction D1 and the second direction D2). The body part BDP may have a sixth sidewall SW6 extending in the first direction D1. The sixth sidewall SW6 of the body part BDP may be substantially perpendicular to the third sidewall SW3 of the first semiconductor pattern SP1. A first angle θ1 between the fifth sidewall SW5 of the channel neighboring part CNP and the third sidewall SW3 of the first semiconductor pattern SP1 may be less than about 90°. For example, the first angle θ1 may range from about 30° to about 80°.

The gate spacer GS may be provided on the fifth and sixth sidewalls SW5 and SW6 of the gate electrode GE. The gate spacer GS may include a first spacer GS1 and a second spacer GS2. Each of the first spacer GS1 and the second spacer GS2 may include a Si-containing insulating material.

For example, the first spacer GS1 may include carbon-containing silicon nitride (i.e., SiCN). The first spacer GS1 may have a thickness ranging from about 1 nm to about 3 nm. The first spacer GS1 may cover the gate insulating layer GI. The first spacer GS1 may cover at least a portion of the third sidewall SW3 of the first semiconductor pattern SP1. The first spacer GS1 may be in direct contact with a portion of the first semiconductor layer SEL1.

The second spacer GS2 may include a low-k dielectric material containing Si, for example, SiCON. The second spacer GS2 may have a thickness ranging from about 5 nm to about 12 nm. A dielectric constant of the second spacer GS2 may be less than a dielectric constant of the first spacer GS1. The second spacer GS2 may be disposed on a portion of the second semiconductor layer SEL2. For example, the second spacer GS2 may be in direct contact with a portion of the second semiconductor layer SEL2.

Referring to FIG. 4, the gate electrode GE may be provided on an uppermost portion (i.e., the third semiconductor pattern SP3) of the first channel pattern CH1. The gate electrode GE may include a channel neighboring part CNP and a body part BDP. The channel neighboring part CNP may be adjacent to the third semiconductor pattern SP3, and the body part BDP may be disposed on the channel neighboring part CNP.

The third semiconductor pattern SP3 may have a fourth width W4 in the second direction D2. The channel neighboring part CNP of FIG. 4 may have a fifth width W5 in the second direction D2. The fifth width W5 may increase toward a direction (e.g., the third direction D3) away from the third semiconductor pattern SP3. The fifth width W5 may be less than the fourth width W4.

The body part BDP may have a sixth width W6 in the second direction D2. The sixth width W6 may be greater than the fifth width W5. In an exemplary embodiment of the present inventive concept, the sixth width W6 may be less than the fourth width W4. In addition, in an exemplary embodiment of the present inventive concept, the sixth width W6 may be equal to or greater than the fourth width W4.

The channel neighboring part CNP may have a seventh sidewall SW7 extending diagonally, for example, in a direction between the second and third directions. The body part BDP may have an eighth sidewall SW8 connected to the seventh sidewall SW7. The eighth sidewall SW8 of the body part BDP may be substantially perpendicular to a top surface of the third semiconductor pattern SP3. A second angle θ2 between the seventh sidewall SW7 of the channel neighboring part CNP and the top surface of the third semiconductor pattern SP3 may be less than about 90°. For example, the second angle θ2 may range from about 30° to about 80°. In an exemplary embodiment of the present inventive concept, the second angle θ2 may be substantially equal to the first angle θ1 of FIG. 3.

The gate spacer GS may be provided on the sidewalls SW7 and SW8 of the gate electrode GE. For example, a width of the gate spacer GS in the second direction D2 may increase in a portion adjacent to the channel neighboring part CNP. The gate spacer GS may include the first spacer GS1 and the second spacer GS2. For example, the first spacer GS1 may cover at least a portion of the top surface of the third semiconductor pattern SP3. For example, the second spacer GS2 might not contact the second semiconductor layer SEL2.

According to a comparative example, a width of a portion, adjacent directly to a channel, of a gate electrode GE may be greater than a width of another portion of the gate electrode GE. In other words, a gate skirt structure in which a width of the gate electrode GE becomes progressively greater toward the channel may be generally formed. The gate skirt structure may cause a process defect such as damage of a source/drain pattern.

However, according to an exemplary embodiment of the present inventive concept, the channel neighboring part CNP of the gate electrode GE may have a tapered structure in which a width becomes progressively less toward the channel. In other words, the width of the portion, adjacent to the channel, of the gate electrode GE may be selectively reduced. Since the width of the channel neighboring part CNP is reduced, the width (or, e.g., thickness) of the gate spacer GS on the channel neighboring part CNP may be increased. For example, the width (or, e.g., thickness) of the gate spacer GS on the eighth sidewall SW8 of the body part BDP may be less than the width of the gate spacer GS on the seventh sidewall SW7 of the channel neighboring pattern CNP. A distance between the gate electrode GE and the first source/drain pattern SD1 may be increased due to the increase in the width of the gate spacer GS and the reduction in the width of the channel neighboring part CNP. As a result, according to an embodiment of the present inventive concept, a process defect in which the source/drain pattern may be damaged in formation of the gate electrode GE may be prevented, and reliability of the semiconductor device may be increased.

The gate electrode GE, the gate spacer GS, the second channel pattern CH2 and the second source/drain pattern SD2 on the NMOSFET region NR may be substantially the same or similar as illustrated in FIGS. 3 and 4.

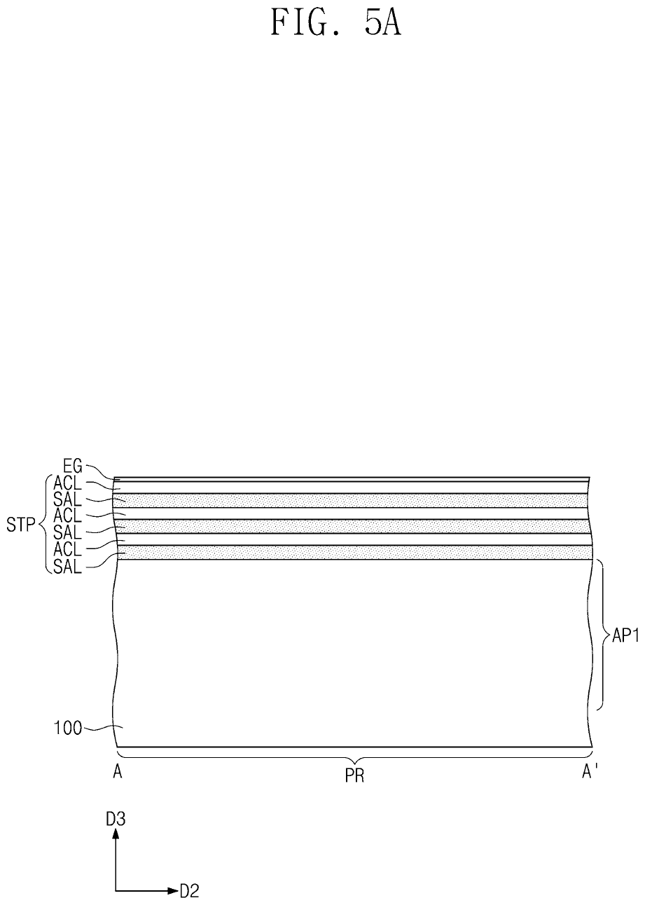

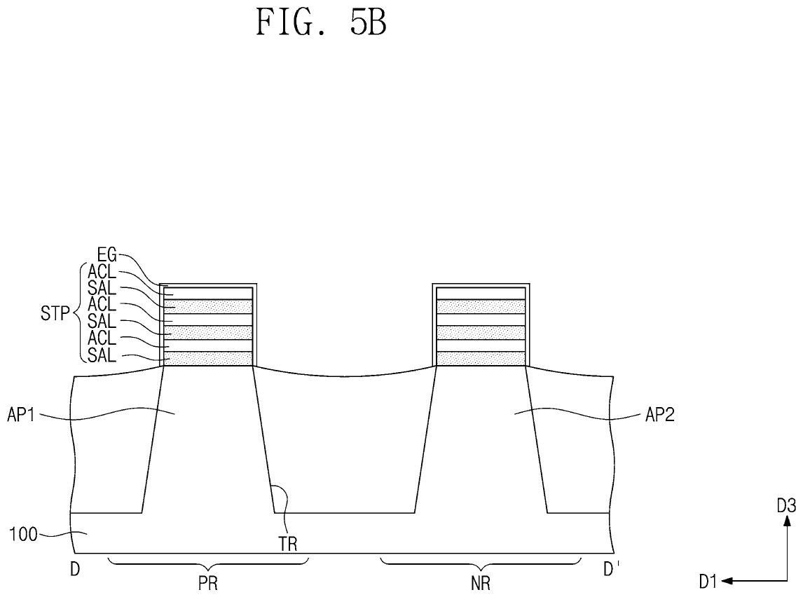

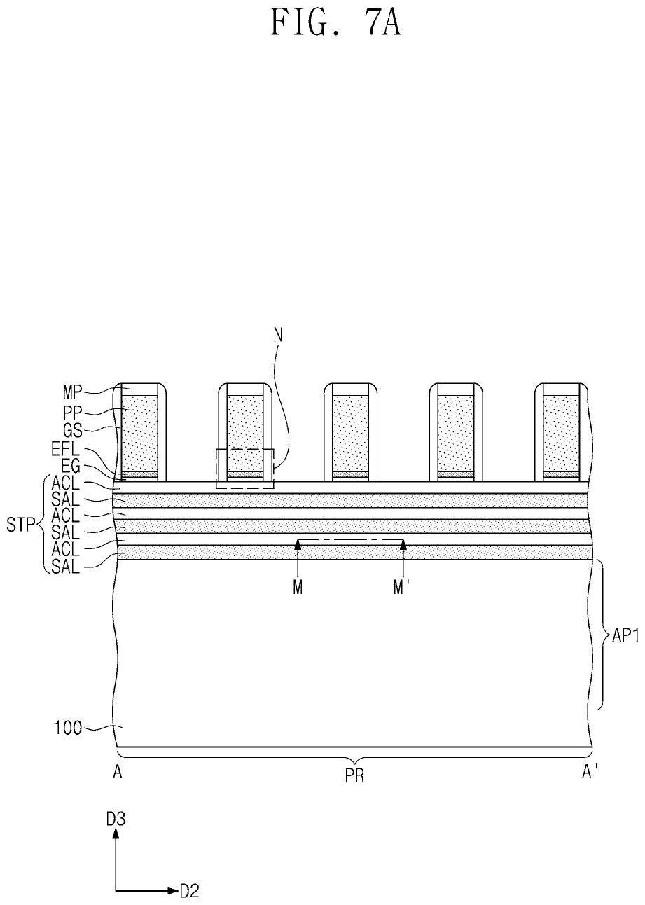

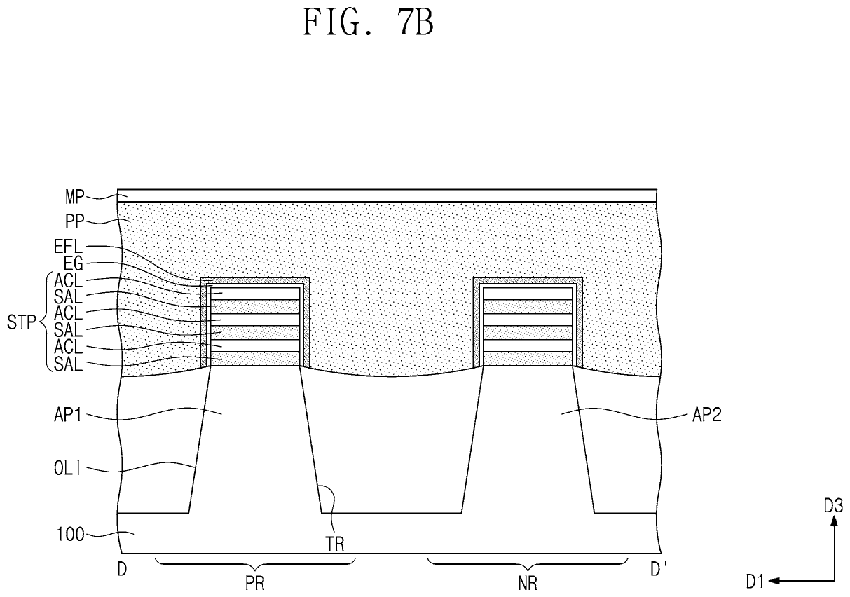

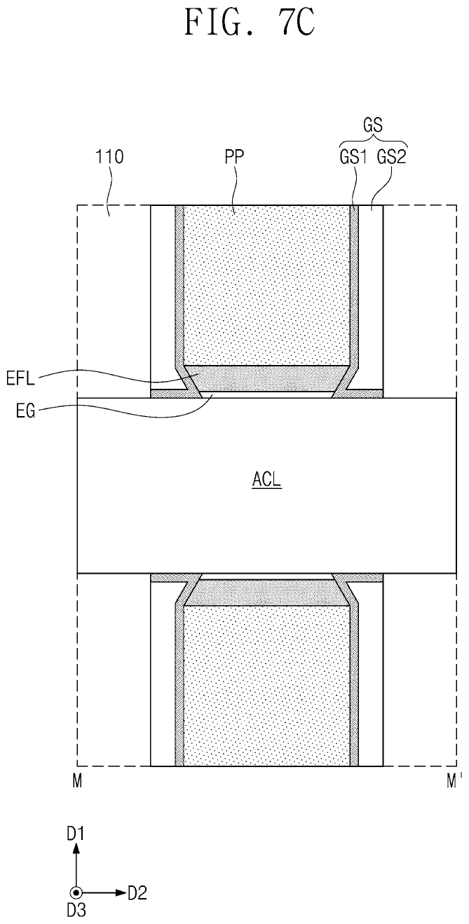

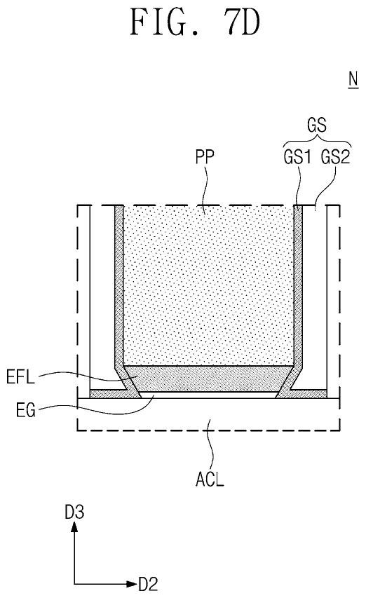

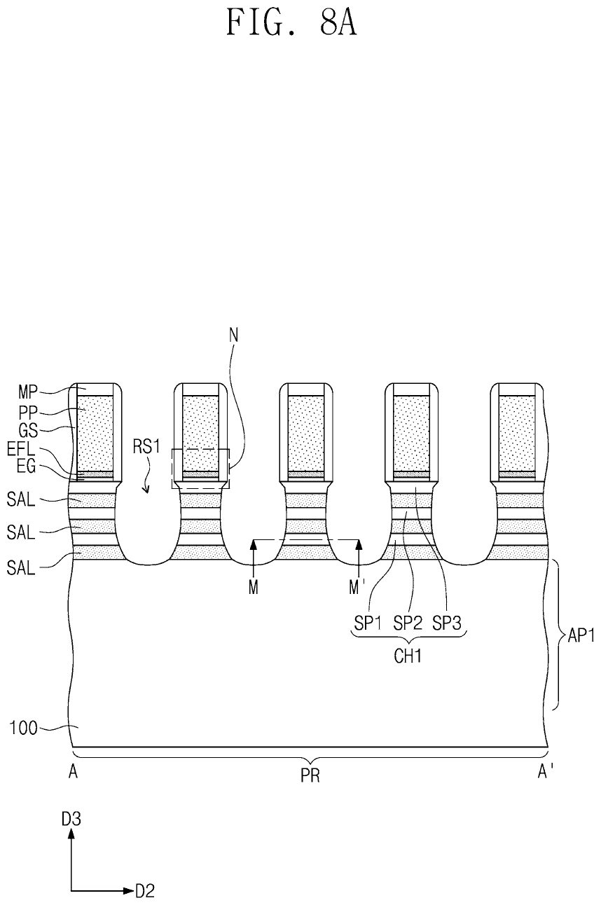

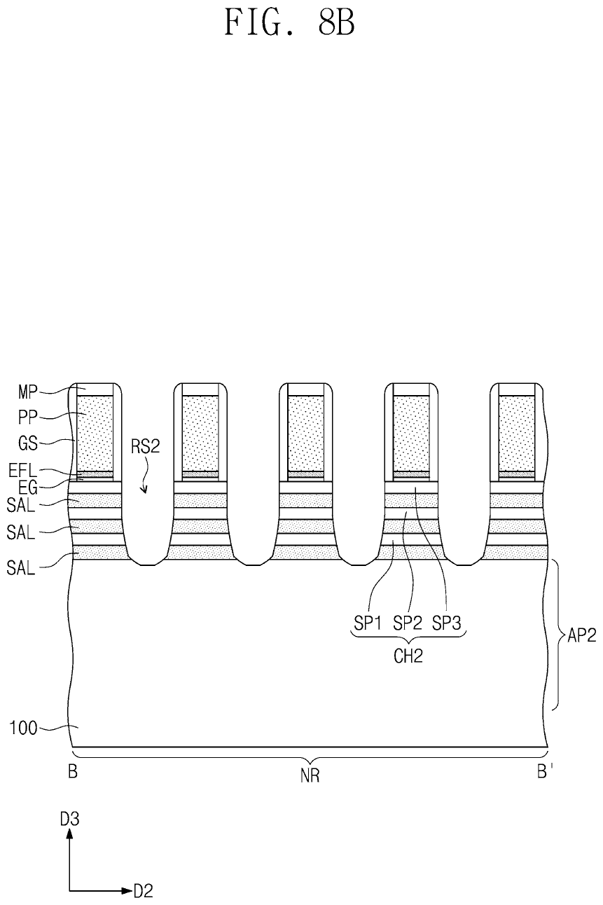

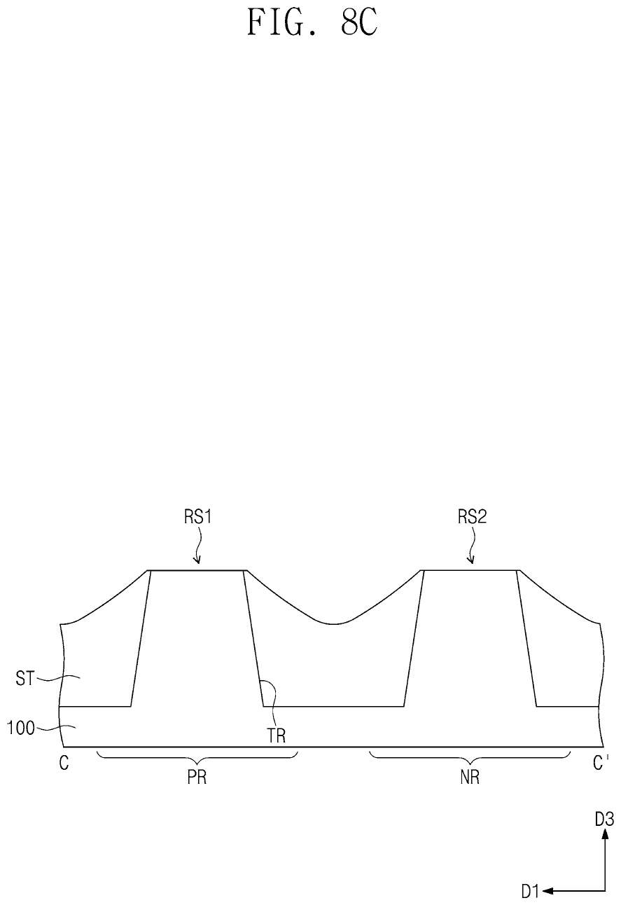

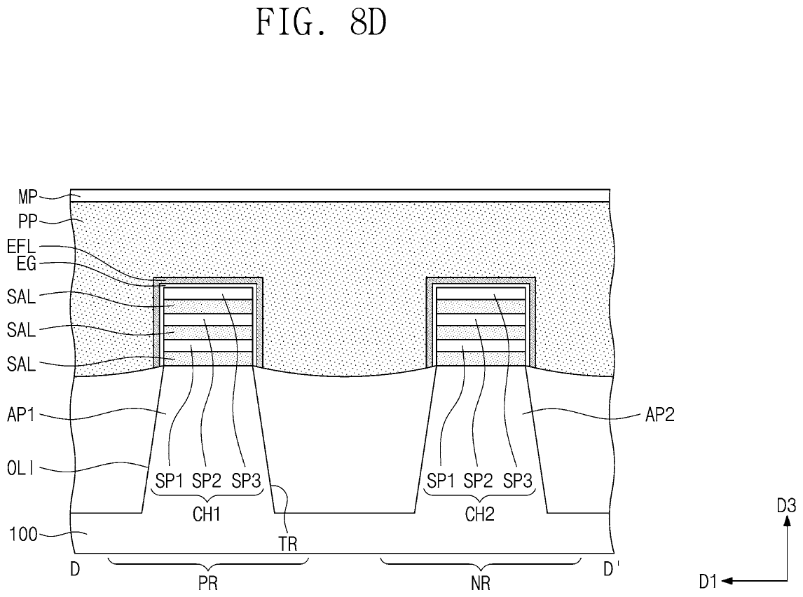

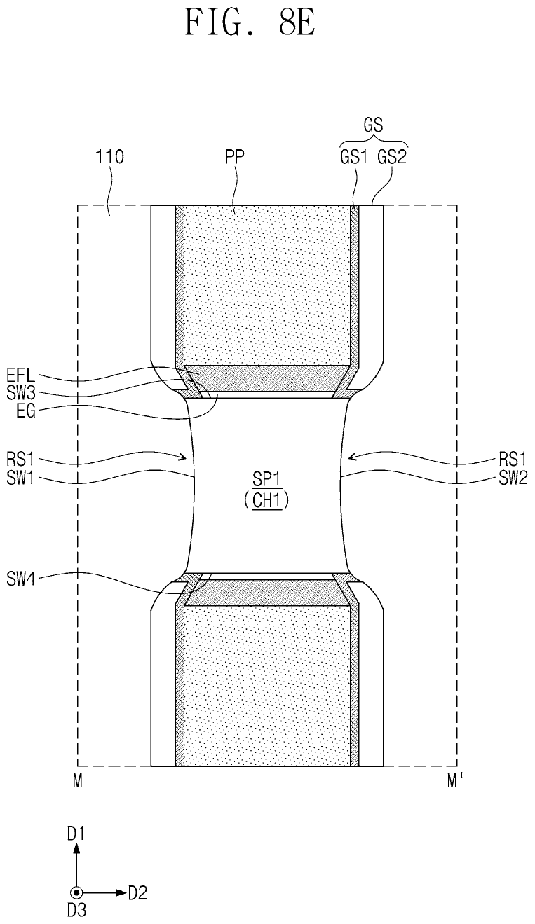

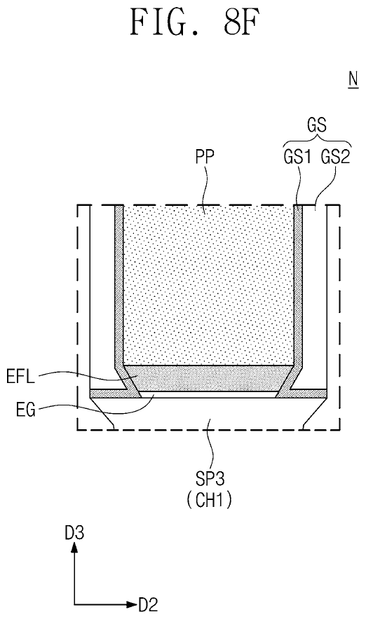

FIGS. 5A to 11D are views illustrating a method for manufacturing a semiconductor device according to an exemplary embodiment of the present inventive concept. In particular, FIGS. 5A, 6A, 7A, 8A, 9A, 10A and 11A are cross-sectional views corresponding to the line A-A′ of FIG. 1. FIGS. 8B, 9B, 10B and 11B are cross-sectional views corresponding to the line B-B′ of FIG. 1. FIGS. 8C, 9C, 10C and 11C are cross-sectional views corresponding to the line C-C′ of FIG. 1. FIGS. 5B, 6B, 7B, 8D, 9D, 10D and 11D are cross-sectional views corresponding to the line D-D′ of FIG. 1. FIGS. 7C, 8E, 9E and 10E are enlarged plan views taken along line M-M′ of FIGS. 7A, 8A, 9A and 10A, respectively. FIGS. 7D, 8F, 9F and 10F are enlarged cross-sectional views of regions ‘N’ of FIGS. 7A, 8A, 9A and 10A, respectively.

Referring to FIGS. 1, 5A and 5B, a substrate 100 including a logic cell LC may be provided. The substrate 100 may include a PMOSFET region PR and an NMOSFET region NR. Sacrificial layers SAL and active layers ACL may be alternately formed on the substrate 100. For example, the sacrificial layers SAL may include at least one of silicon (Si), germanium (Ge) and/or silicon-germanium (SiGe), and the active layers ACL may include at least one of silicon (Si), germanium (Ge) and/or silicon-germanium (SiGe).

For example, the sacrificial layers SAL may include silicon-germanium (SiGe), and the active layers ACL may include silicon (Si). A concentration of germanium (Ge) of each of the sacrificial layers SAL may range from about 10 at % to about 30 at %.

Mask patterns may be formed on the PMOSFET region PR and the NMOSFET region NR of the substrate 100, respectively. Each of the mask patterns may have a line shape or bar shape extending in the second direction D2.

A patterning process may be performed using the mask patterns as etch masks to form a trench TR defining a first active pattern AP1 and a second active pattern AP2. The first active pattern AP1 and the second active pattern AP2 may be formed on the PMOSFET region PR and the NMOSFET region NR, respectively. A stack pattern STP may be formed on each of the first and second active patterns AP1 and AP2. The stack pattern STP may include the sacrificial layers SAL and the active layers ACL, which are alternately stacked on each other. The stack patterns STP may be formed together with the first and second active patterns AP1 and AP2 in the patterning process.

A device isolation layer ST filling the trench TR may be formed. For example, an insulating layer covering the first and second active patterns AP1 and AP2, and the stack patterns STP may be formed on an entire top surface of the substrate 100. The insulating layer may be recessed until the stack patterns STP are exposed, thereby forming the device isolation layer ST.

The device isolation layer ST may include an insulating material (e.g., silicon oxide). The stack patterns STP may be exposed above the device isolation layer ST. In other words, the stack patterns STP may vertically protrude above the device isolation layer ST.

An oxide layer EG may be formed on the stack pattern STP exposed above the device isolation layer ST. The oxide layer EG may be conformally formed on the stack pattern STP. For example, the oxide layer EG may include a silicon oxide layer.

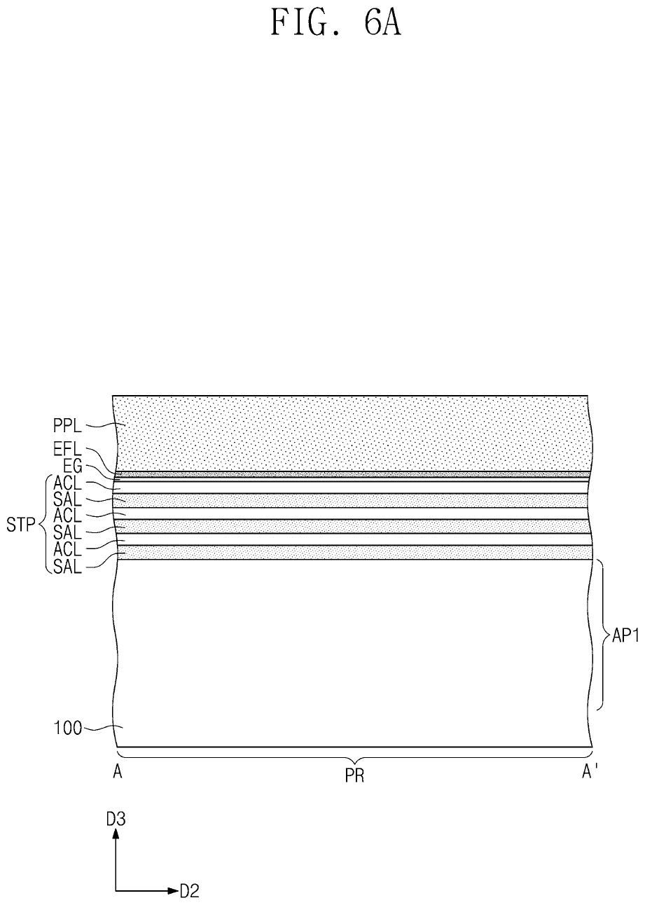

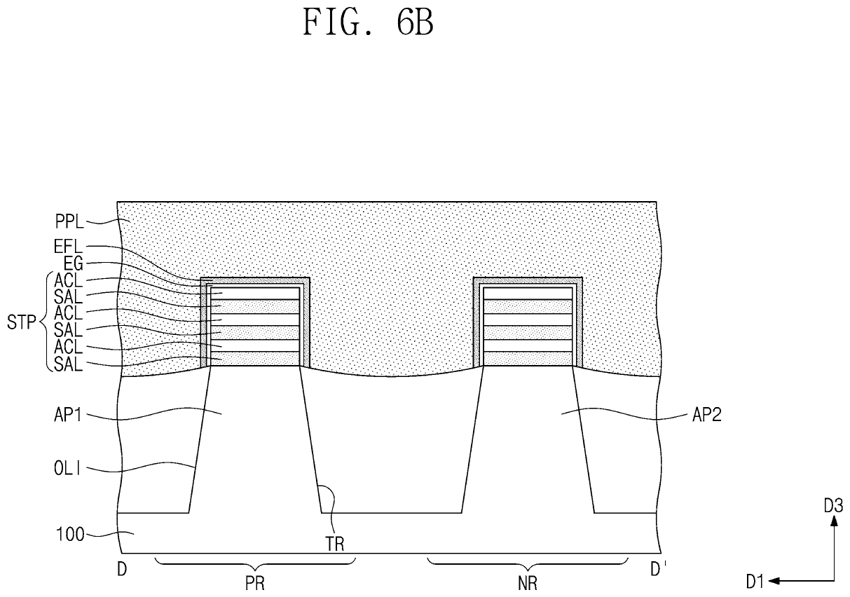

Referring to FIGS. 1, 6A and 6B, an etch facilitation layer EFL and a sacrificial semiconductor layer PPL may be sequentially formed on the substrate 100. The etch facilitation layer EFL may be formed on the oxide layer EG. For example, the etch facilitation layer EFL may be formed directly on the oxide layer EG. The sacrificial semiconductor layer PPL may be formed on the etch facilitation layer EFL. The sacrificial semiconductor layer PPL may include, for example, amorphous silicon (Si) or poly-silicon (Si).

The etch facilitation layer EFL may be formed adjacent to the active layers ACL of the stack pattern STP. The sacrificial semiconductor layer PPL may be spaced apart from the active layers ACL of the stack pattern STP with the oxide layer EG and the etch facilitation layer EFL interposed therebetween. The etch facilitation layer EFL may be formed with a thickness similar to that of the oxide layer EG. For example, the etch facilitation layer EFL may be conformally formed with a thickness ranging from about 1 nm to about 5 nm.

The etch facilitation layer EFL may include a material having an etch rate higher than that of the sacrificial semiconductor layer PPL. The etch facilitation layer EFL may be amorphous. For example, the etch facilitation layer EFL may include silicon-germanium (SiGe), carbon (C)-containing silicon-germanium (SiGeC), silicon carbide (SiC), and/or germanium (Ge).

When the etch facilitation layer EFL includes germanium (Ge), a concentration of germanium (Ge) of the etch facilitation layer EFL may range from about 2 at % to about 100 at %. The concentration of germanium (Ge) of the etch facilitation layer EFL may be greater than a concentration of germanium (Ge) of the sacrificial layers SAL. For example, the concentration of germanium (Ge) of the etch facilitation layer EFL may range from about 20 at % to about 50 at %.

To etch the etch facilitation layer EFL, the etch facilitation layer EFL may additionally include impurities. The etch facilitation layer EFL may further include at least one of boron (B), phosphorus (P), and/or oxygen (O), as the impurities. A concentration of the impurities in the etch facilitation layer EFL may range from about 1 at % to 90 at %. For example, the concentration of the impurities in the etch facilitation layer EFL may range from about 1 at % to about 10 at %.

Referring to FIGS. 1 and 7A to 7D, the sacrificial semiconductor layer PPL may be etched to form sacrificial patterns PP. Each of the sacrificial patterns PP may be formed to have a line shape or bar shape extending in the first direction D1. The sacrificial patterns PP may be arranged in the second direction D2 at a predetermined pitch.

For example, the formation of the sacrificial patterns PP may include forming hard mask patterns MP on the sacrificial semiconductor layer PPL, and etching the sacrificial semiconductor layer PPL using the hard mask patterns MP as etch masks. The etch facilitation layer EFL under the sacrificial semiconductor layer PPL may also be etched in the etching of the sacrificial semiconductor layer PPL.

In the etching process of the sacrificial semiconductor layer PPL, the etch facilitation layer EFL may be etched faster than the sacrificial semiconductor layer PPL. In other words, in the etching process, an etch rate of the etch facilitation layer EFL may be greater than an etch rate of the sacrificial semiconductor layer PPL. Thus, a width of the etch facilitation layer EFL in the second direction D2 may be equal to or less than a width of the sacrificial pattern PP in the second direction D2 (see FIGS. 7C and 7D).

After the formation of the sacrificial pattern PP, the oxide layer EG may be selectively etched using the sacrificial pattern PP and the etch facilitation layer EFL as masks. Thus, a portion of the oxide layer EG, which overlaps with the etch facilitation layer EFL, may remain.

A pair of gate spacers GS may be formed on both sidewalls of each of the sacrificial patterns PP, respectively. For example, the gate spacers GS may be formed on two sidewalls of the sacrificial patterns PP and two sidewalls of the etch facilitation layer EFL, and thicknesses of the gate spacers GS on the two sidewalls of etch facilitation layer EFL may be greater than thicknesses of the gate spacers GS on the two sidewalls of the sacrificial patterns PP. The formation of the gate spacers GS may include conformally forming a gate spacer layer on a top surface of the substrate 100, and anisotropically etching the gate spacer layer. The gate spacer layer may include at least one of SiCN, SiCON, and/or SiN. For example, the gate spacer GS may include a first spacer GS1 and a second spacer GS2. The first spacer GS1 may be disposed on a sidewall of the sacrificial pattern PP, and the second spacer GS2 may be disposed on the first spacer GS1.

Referring to FIGS. 1 and 8A to 8F, first recesses RS1 may be formed in the stack pattern STP that is disposed on the first active pattern AP1. Second recesses RS2 may be formed in the stack pattern STP that is disposed on the second active pattern AP2. The device isolation layer ST at opposing sides of each of the first and second active patterns AP1 and AP2 may be further recessed during the formation of the first and second recesses RS1 and RS2 (see FIG. 8C).

For example, the stack pattern STP that is disposed on the first active pattern AP1 may be etched using the hard mask patterns MP and the gate spacers GS as etch masks to form the first recesses RS1. The first recess RS1 may be formed between a pair of the sacrificial patterns PP. The second recesses RS2 in the stack pattern STP that is disposed on the second active pattern AP2 may be formed by the same method as the first recesses RS1.

First to third semiconductor patterns SP1, SP2 and SP3 stacked sequentially may be formed from the active layers ACL between the first recesses RS1 adjacent to each other. First to third semiconductor patterns SP1, SP2 and SP3 stacked sequentially may be formed from the active layers ACL between the second recesses RS2 adjacent to each other. The first to third semiconductor patterns SP1, SP2 and SP3 between the first recesses RS1 adjacent to each other may form a first channel pattern CH1. The first to third semiconductor patterns SP1, SP2 and SP3 between the second recesses RS2 adjacent to each other may form a second channel pattern CH2.

Referring again to FIG. 8E, first and second sidewalls SW1 and SW2 opposite to each other in the second direction D2 may be formed at the first semiconductor pattern SP1 by the first recesses RS1. Each of the first and second sidewalls SW1 and SW2 may be exposed by the first recess RS1. Each of the first and second sidewalls SW1 and SW2 may have a concave profile.

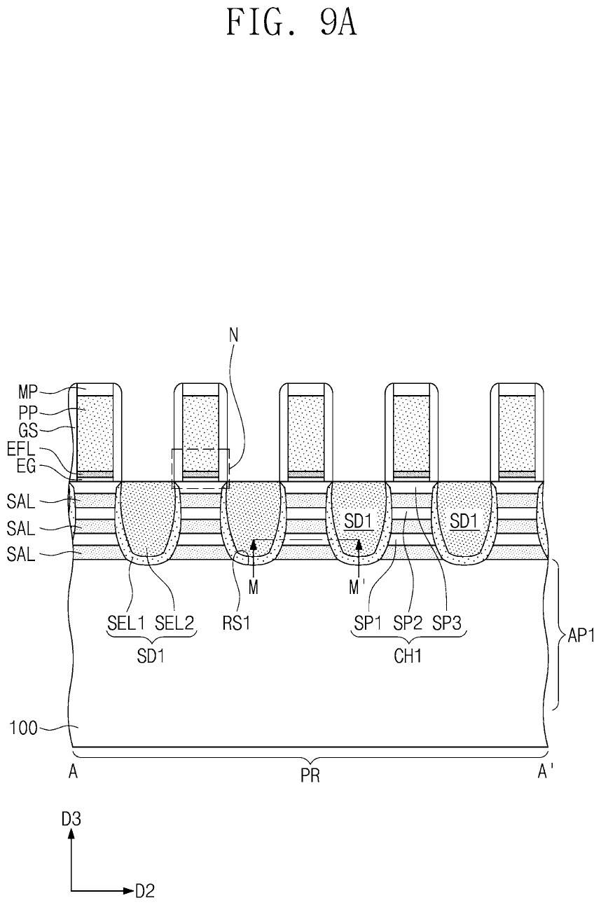

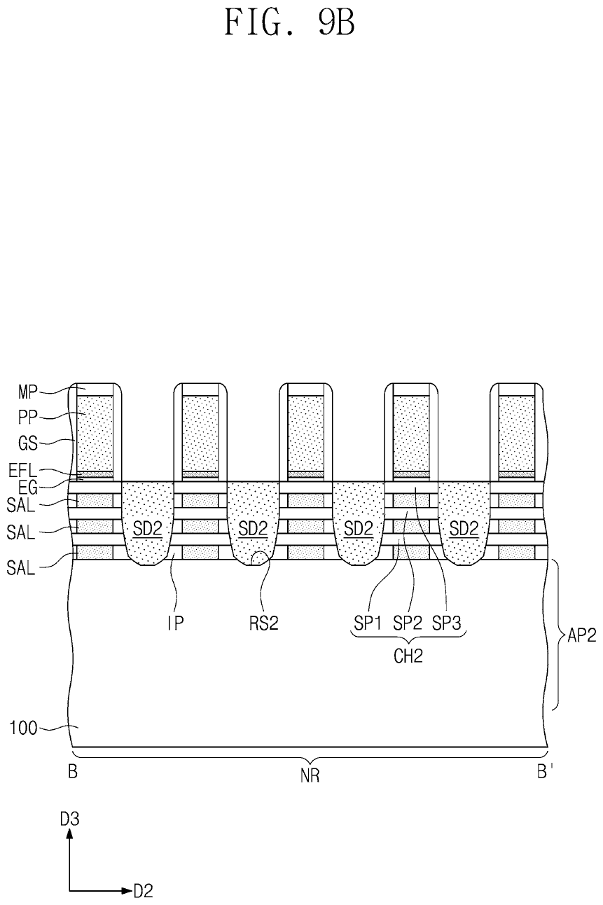

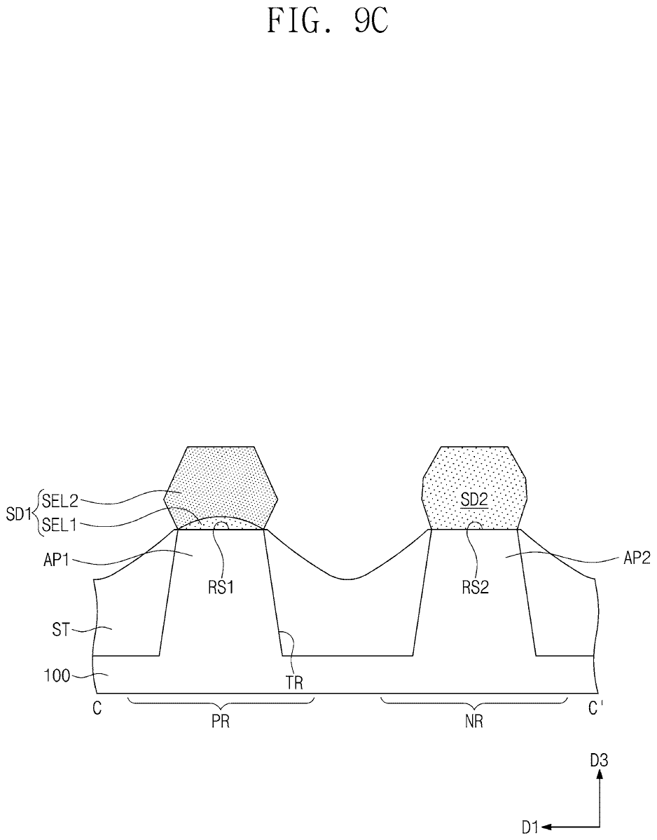

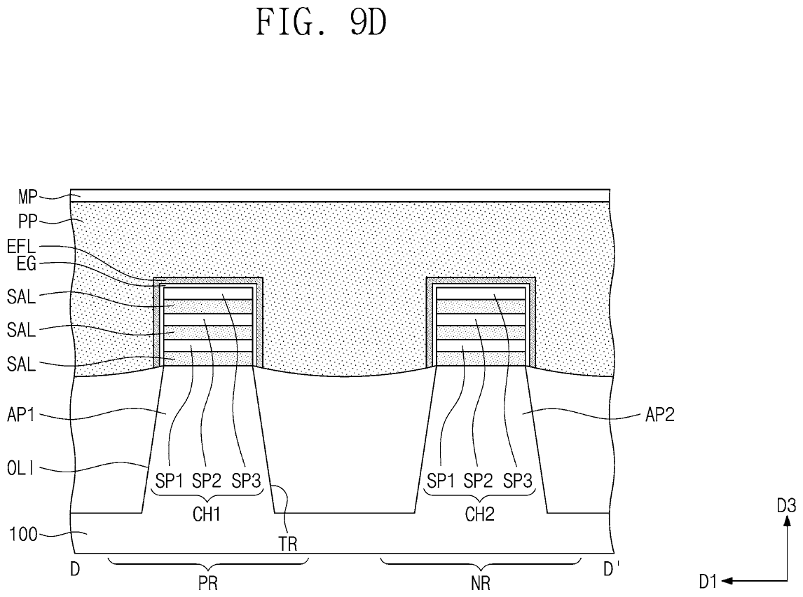

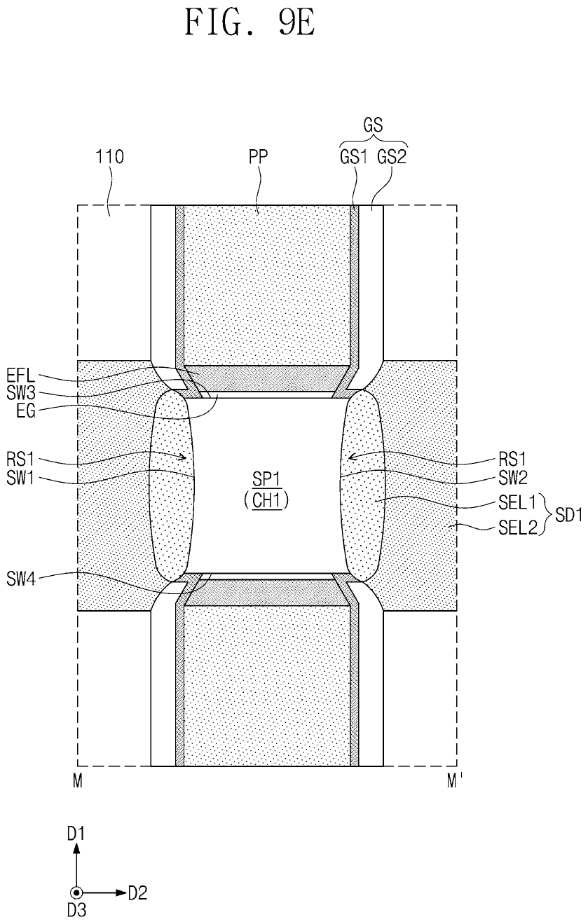

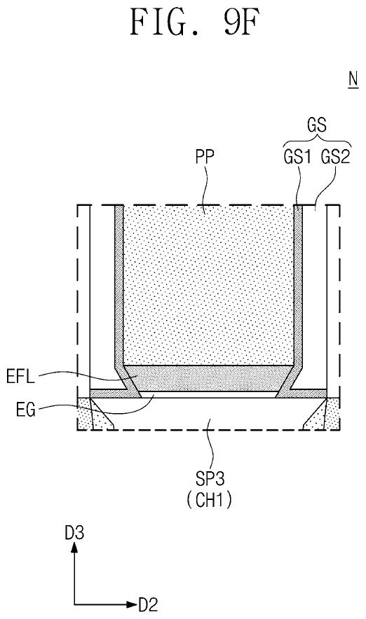

Referring to FIGS. 1 and 9A to 9F, first source/drain patterns SD1 may be formed in the first recesses RS1, respectively. For example, a first selective epitaxial growth (SEG) process may be performed using an inner surface of the first recess RS1 as a seed layer to form a first semiconductor layer SEL1. The first semiconductor layer SEL1 may be grown using the first to third semiconductor patterns SP1, SP2 and SP3, the sacrificial layers SAL and the substrate 100, which are exposed by the first recess RS1, as a seed layer. For example, the first semiconductor layer SEL1 may be formed on each of the first and second sidewalls SW1 and SW2 of the first semiconductor pattern SP1 (see FIG. 9E). The first SEG process may include a chemical vapor deposition (CVD) process or a molecular beam epitaxy (MBE) process.

The first semiconductor layer SEL1 may include a semiconductor element (e.g., SiGe) of which a lattice constant is greater than a lattice constant of a semiconductor element of the substrate 100. The first semiconductor layer SEL1 may include a relatively low concentration of germanium (Ge). In an exemplary embodiment of the present inventive concept, the first semiconductor layer SEL1 may include silicon (Si) except germanium (Ge). A concentration of germanium (Ge) of the first semiconductor layer SEL1 may range from about 0 at % to about 10 at %.

A second SEG process may be performed on the first semiconductor layer SEL1 to form a second semiconductor layer SEL2. The second semiconductor layer SEL2 may be formed to fill the first recess RS1. For example, the second semiconductor layer SEL2 may be formed to completely fill the first recess RS1. The second semiconductor layer SEL2 may include a relatively high concentration of germanium (Ge). For example, a concentration of germanium (Ge) of the second semiconductor layer SEL2 may range from about 30 at % to about 70 at %.

The first semiconductor layer SEL1 and the second semiconductor layer SEL2 may form the first source/drain pattern SD1. Dopants may be injected in-situ during the first and second SEG processes. In addition, after the formation of the first source/drain pattern SD1, dopants may be injected or implanted into the first source/drain pattern SD1. The first source/drain pattern SD1 may be doped to have a first conductivity type (e.g., a p-type).

Second source/drain patterns SD2 may be formed in the second recesses RS2, respectively. For example, the second source/drain pattern SD2 may be formed by performing a SEG process using an inner surface of the second recess RS2 as a seed layer. For example, the second source/drain pattern SD2 may include the same semiconductor element (e.g., Si) as the substrate 100. The second source/drain pattern SD2 may be doped to have a second conductivity type (e.g., an n-type). Inner spacers IP may be formed between the second source/drain pattern SD2 and the sacrificial layers SAL, respectively.

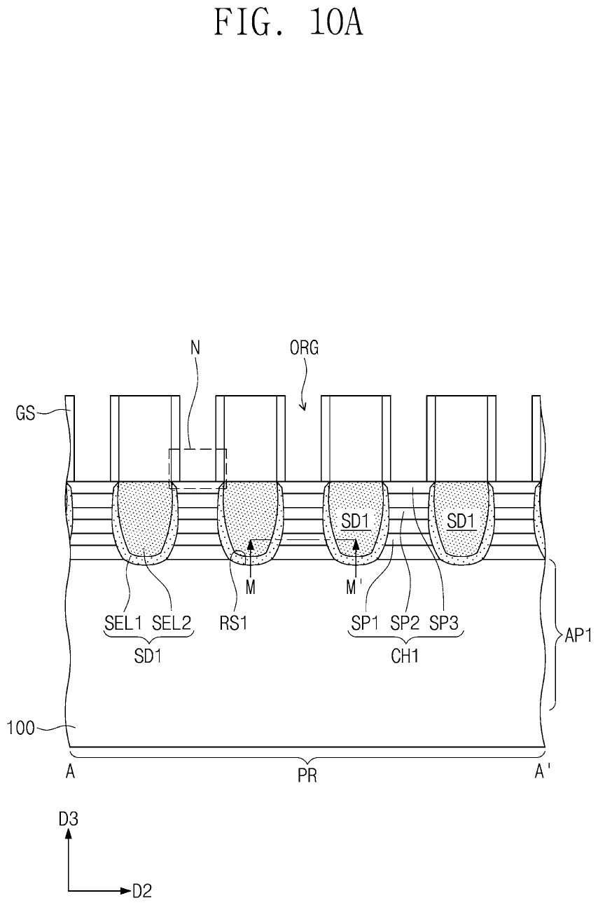

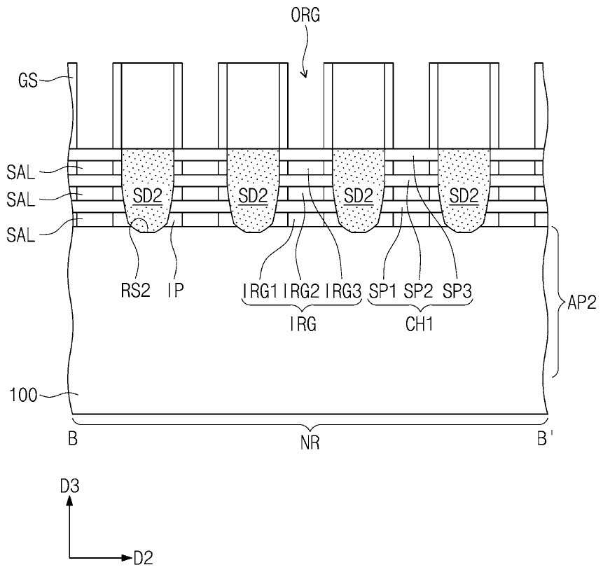

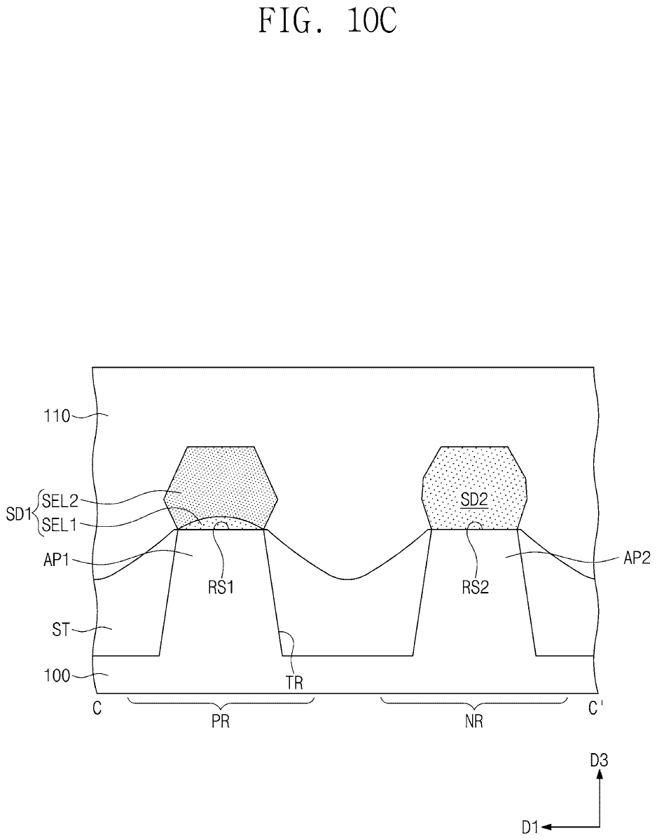

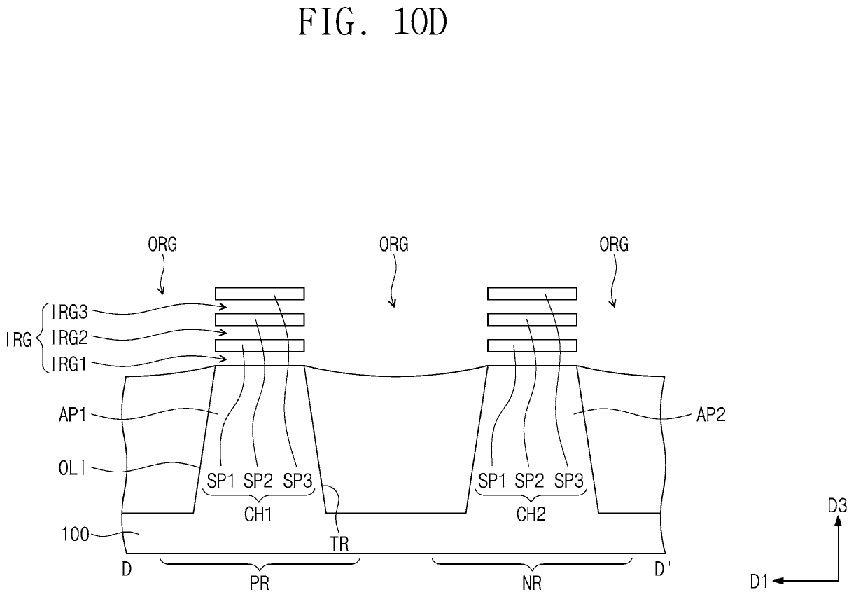

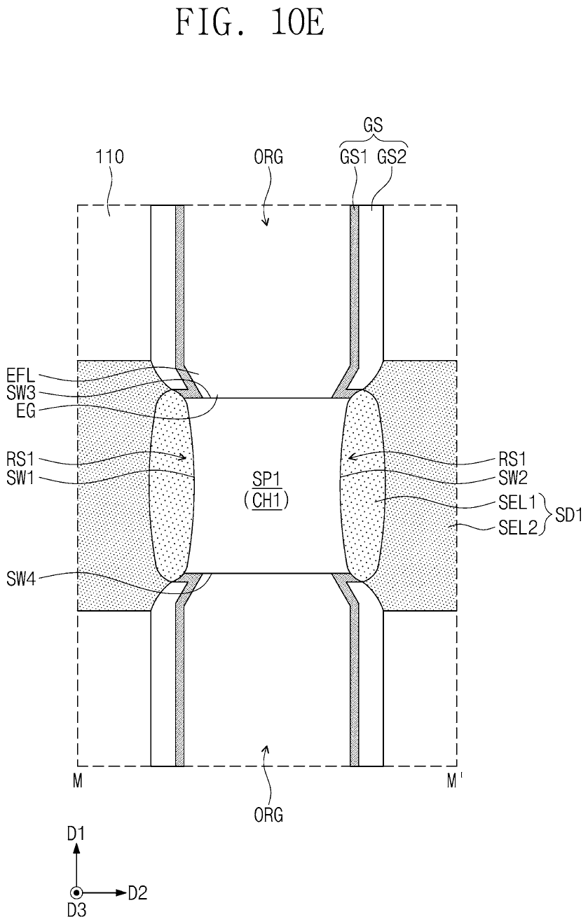

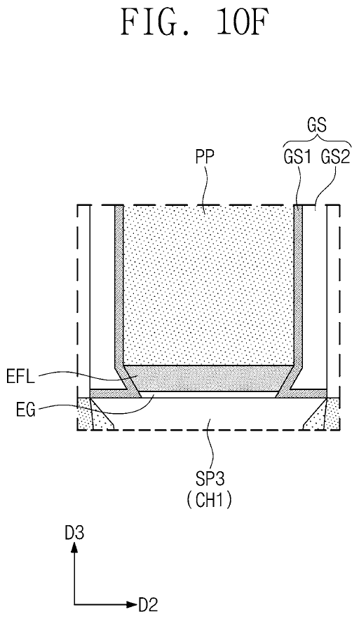

Referring to FIGS. 1 and 10A to 10F, a first interlayer insulating layer 110 may be formed to cover the first and second source/drain patterns SD1 and SD2, the hard mask patterns MP and the gate spacers GS. For example, the first interlayer insulating layer 110 may include a silicon oxide layer.

The first interlayer insulating layer 110 may be planarized to expose top surfaces of the sacrificial patterns PP. For example, the planarization of the first interlayer insulating layer 110 may be performed using an etch-back process or a chemical mechanical polishing (CMP) process. The hard mask patterns MP may be completely removed during the planarization process. As a result, a top surface of the first interlayer insulating layer 110 may be substantially coplanar with the top surfaces of the sacrificial patterns PP and top surfaces of the gate spacers GS.

The exposed sacrificial pattern PP, the etch facilitation layer EFL and the oxide layer EG may be removed. An outer region ORG exposing the first and second channel patterns CH1 and CH2 may be formed by the removal of the sacrificial pattern PP, the etch facilitation layer EFL and the oxide layer EG (see FIGS. 10D and 10E).

Since the sacrificial pattern PP, the etch facilitation layer EFL and the oxide layer EG are removed, the sacrificial layers SAL may be exposed through the outer region ORG. The exposed sacrificial layers SAL may be selectively removed to form inner regions IRG (see FIG. 10D). For example, an etching process of selectively etching the sacrificial layers SAL may be performed to remove the sacrificial layers SAL while leaving the first to third semiconductor patterns SP1, SP2 and SP3. The etching process may have a high etch rate with respect to silicon-germanium having a relatively high germanium concentration. For example, the etching process may have a high etch rate with respect to silicon-germanium that has a germanium concentration greater than about 10 at %.

The sacrificial layers SAL disposed on the PMOSFET region PR and the NMOSFET region NR may be removed during the etching process. The etching process may be a wet etching process. An etching material used in the etching process may remove the sacrificial layer SAL that has a relatively high germanium concentration. In addition, the first source/drain pattern SD1 of the PMOSFET region PR may be protected during the etching process by the first semiconductor layer SEL1 having a relatively low germanium concentration.

Referring again to FIG. 10D, since the sacrificial layers SAL are selectively removed, the first to third semiconductor patterns SP1, SP2 and SP3 that are stacked on each other and spaced apart from each other may remain on each of the first and second active patterns AP1 and AP2. First to third inner regions IRG1, IRG2 and IRG3 may be formed by the removal of the sacrificial layers SAL. For example, the first inner region IRG1 may be formed between the active pattern AP1 and/or AP2 and the first semiconductor pattern SP1. The second inner region IRG2 may be formed between the first semiconductor pattern SP1 and the second semiconductor pattern SP2, and the third inner region IRG3 may be formed between the second semiconductor pattern SP2 and the third semiconductor pattern SP3.

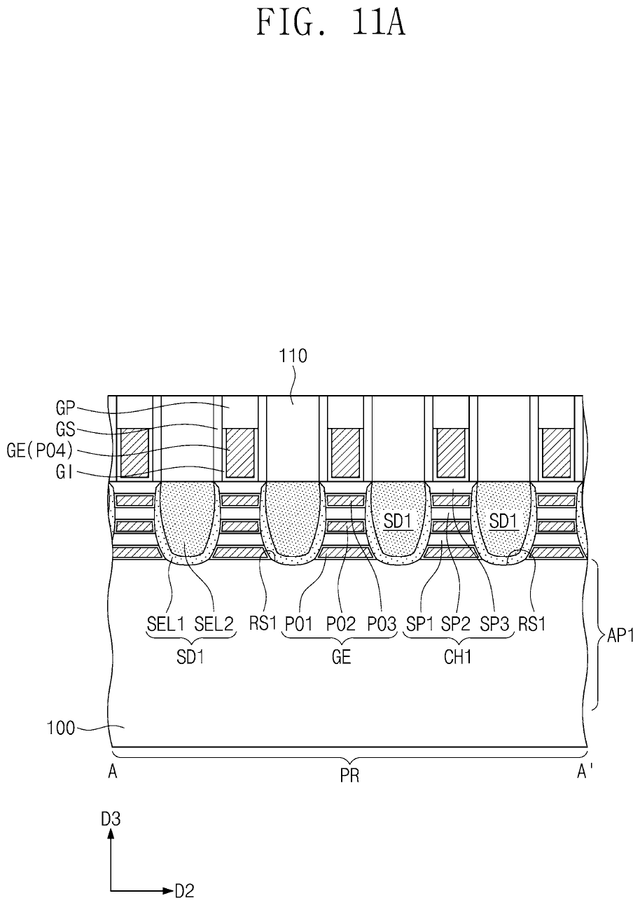

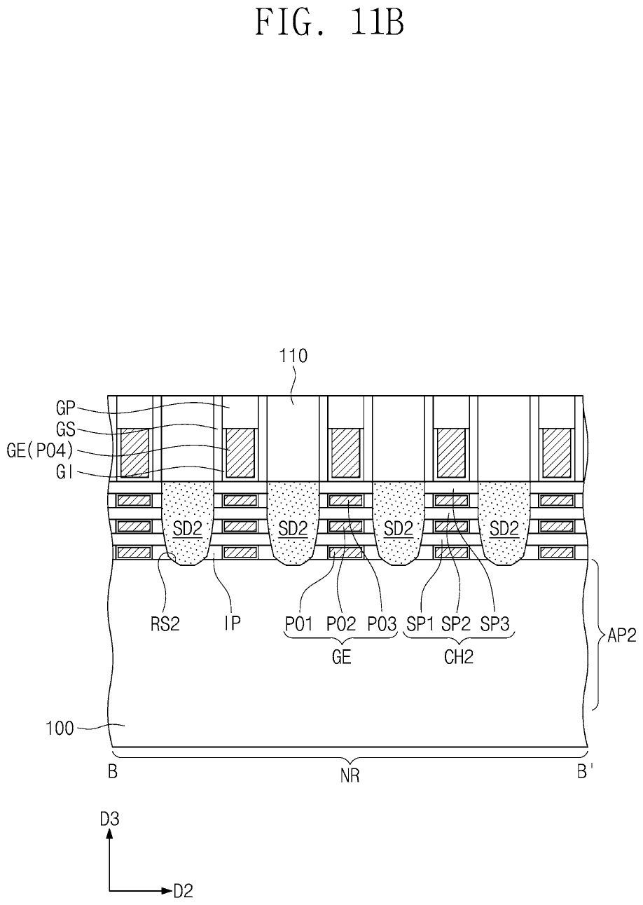

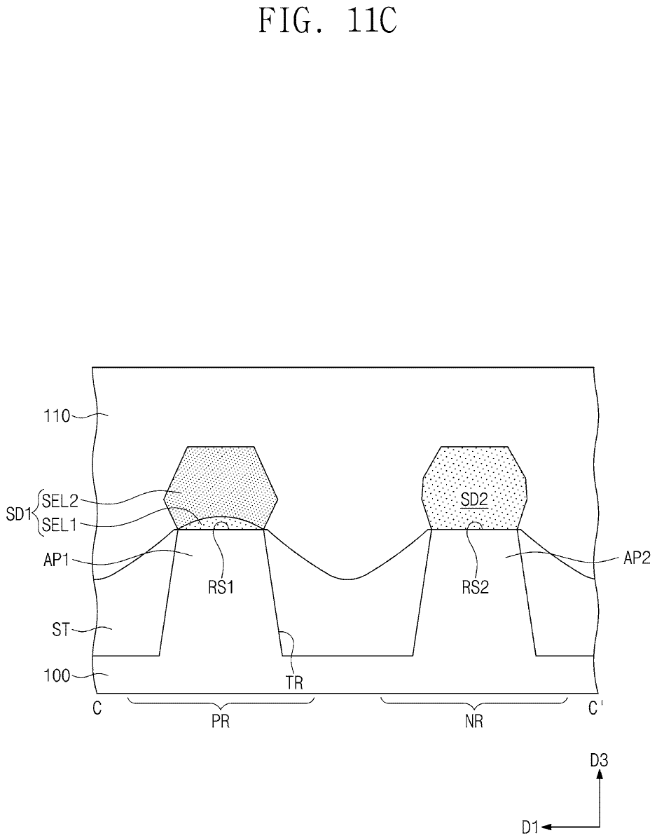

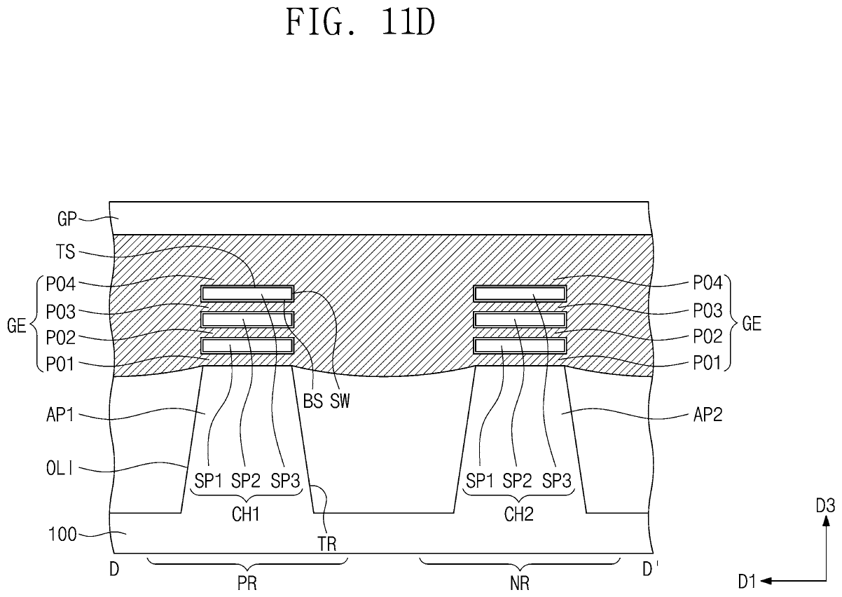

Referring to FIGS. 1 and 11A to 11D, a gate insulating layer GI may be conformally formed on the exposed first to third semiconductor patterns SP1, SP2 and SP3. A gate electrode GE may be formed on the gate insulating layer GI. A gate capping pattern GP may be formed on the gate electrode GE.

The gate electrode GE may be formed such that it fills the first to third inner regions IRG1, IRG2 and IRG3 and the outer region ORG. The gate electrode GE may include a first portion PO1, a second portion PO2 and a third portion PO3, which fill the first to third inner regions IRG1, IRG2 and IRG3, respectively. The gate electrode GE may include a fourth portion PO4 filling the outer region ORG.

Referring again to FIGS. 1 and 2A to 2D, a second interlayer insulating layer 120 may be formed on the first interlayer insulating layer 110. The second interlayer insulating layer 120 may include, for example, a silicon oxide layer. Active contacts AC may be formed such that they penetrate the second interlayer insulating layer 120 and the first interlayer insulating layer 110, and the active contacts AC may be electrically connected to the first and second source/drain patterns SD1 and SD2. A gate contact GC may be formed to penetrate the second interlayer insulating layer 120 and the gate capping pattern GP, and the gate contact GC may be electrically connected to the gate electrode GE.

A pair of isolation structures DB may be formed at two sides of the logic cell LC, respectively. The isolation structure DB may penetrate the second interlayer insulating layer 120 and the gate electrode GE and may extend into the active patterns AP1 and AP2. The isolation structure DB may include an insulating material such as silicon oxide or silicon nitride.

A third interlayer insulating layer 130 may be formed on the active contacts AC and the gate contacts GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

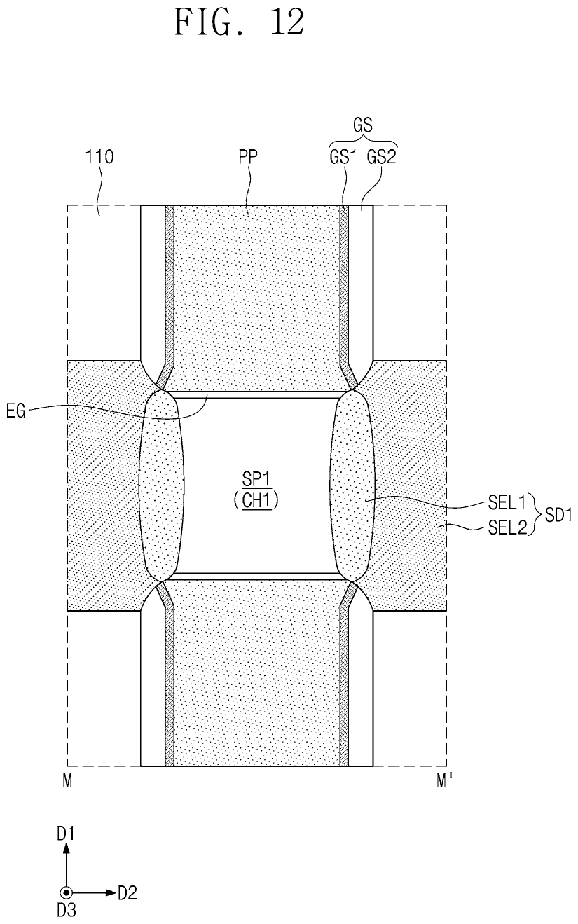

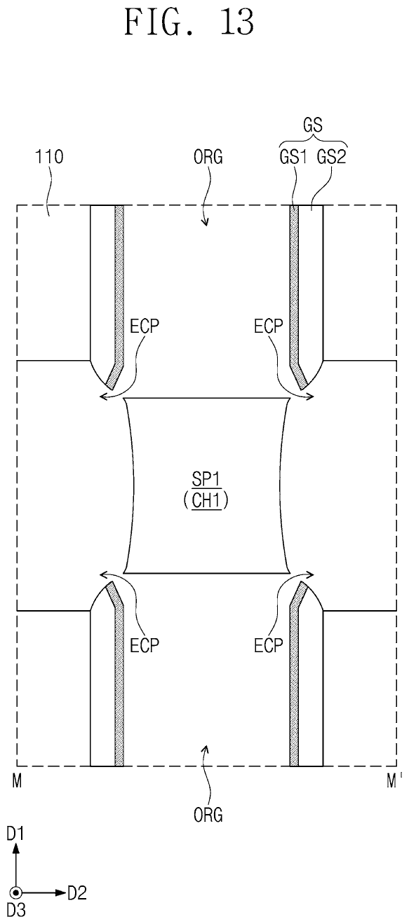

FIGS. 12 and 13 are plan views taken along lines M-M′ of FIGS. 9A and 10A, respectively, to illustrate a method for manufacturing a semiconductor device according to a comparative example.

Referring to FIG. 12, if the etch facilitation layer EFL according to an exemplary embodiment of the present inventive concept is omitted, a width of a portion, adjacent to the first channel pattern CH1, of the sacrificial pattern PP may be increased. In other words, the sacrificial pattern PP may have a gate skirt structure in which its width becomes progressively greater toward a channel.

Since the sacrificial pattern PP has the gate skirt structure, a thickness of the gate spacer GS on the portion of the sacrificial pattern PP may be reduced. Since the sacrificial pattern PP has the gate skirt structure, a distance between the portion of the sacrificial pattern PP and the first source/drain pattern SD1 may be reduced. For example, the portion of the sacrificial pattern PP may be in direct contact with at least a portion of the first source/drain pattern SD1.

Referring to FIG. 13, the sacrificial pattern PP may be removed to form an outer region ORG. The outer region ORG may expose at least a portion of the first source/drain pattern SD1. A process of removing the sacrificial layers SAL may be performed to form the outer region ORG. An etching material ECP for removing the sacrificial layers SAL may be provided into the outer region ORG. The etching material ECP may remove the exposed first source/drain pattern SD1 as well as the sacrificial layers SAL. Unlike FIG. 10E according to an exemplary embodiment of the present inventive concept, a process defect in which the first source/drain pattern SD1 may be removed may occur in the comparative example of FIG. 13.

The method for manufacturing the semiconductor device according to an exemplary embodiment of the present inventive concept may use the etch facilitation layer EFL, and thus the sacrificial pattern PP might not have the gate skirt structure. Accordingly, the present inventive concept may effectively prevent the removal defect of the source/drain pattern described above with reference to FIGS. 12 and 13. As a result, the reliability of the semiconductor device may be increased.

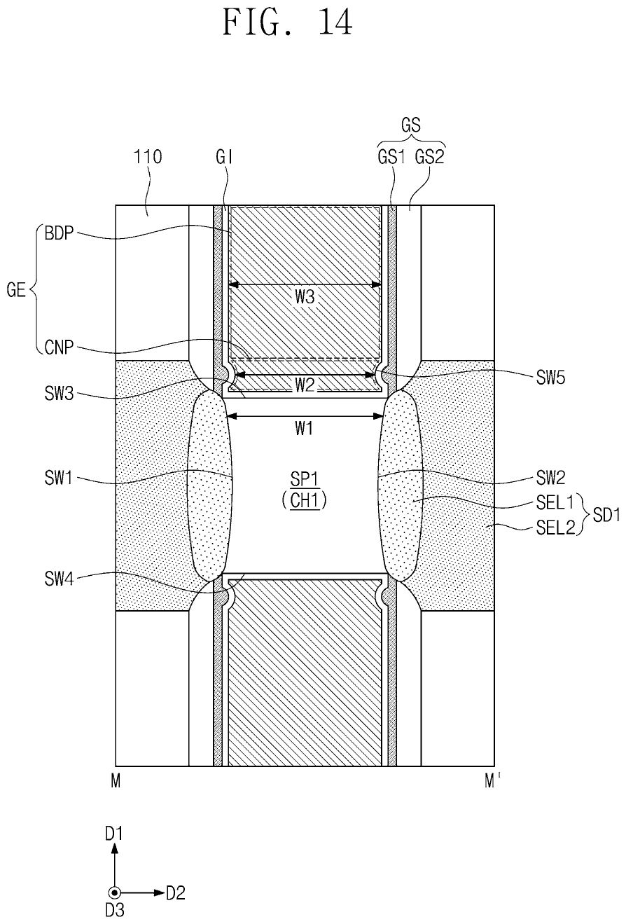

FIG. 14 is a plan view taken along the line M-M′ of FIG. 2A to illustrate a semiconductor device according to an exemplary embodiment of the present inventive concept. In the present embodiment, the descriptions to the same technical features and elements as in the above embodiments of FIGS. 1 to 4 will be omitted for the purpose of ease and convenience in explanation, and differences between the present embodiment and the above embodiments of FIGS. 1 to 4 will be mainly described.

Referring to FIG. 14, a width W2 of the channel neighboring part CNP of the gate electrode GE may decrease and then increase toward the first direction D1. In other words, a fifth sidewall SW5 of the channel neighboring part CNP may have a concave shape. A maximum value of the width W2 of the channel neighboring part CNP may be equal to or less than the third width W3 of the body part BDP. A minimum value of the width W2 of the channel neighboring part CNP may be less than the third width W3 of the body part BDP.

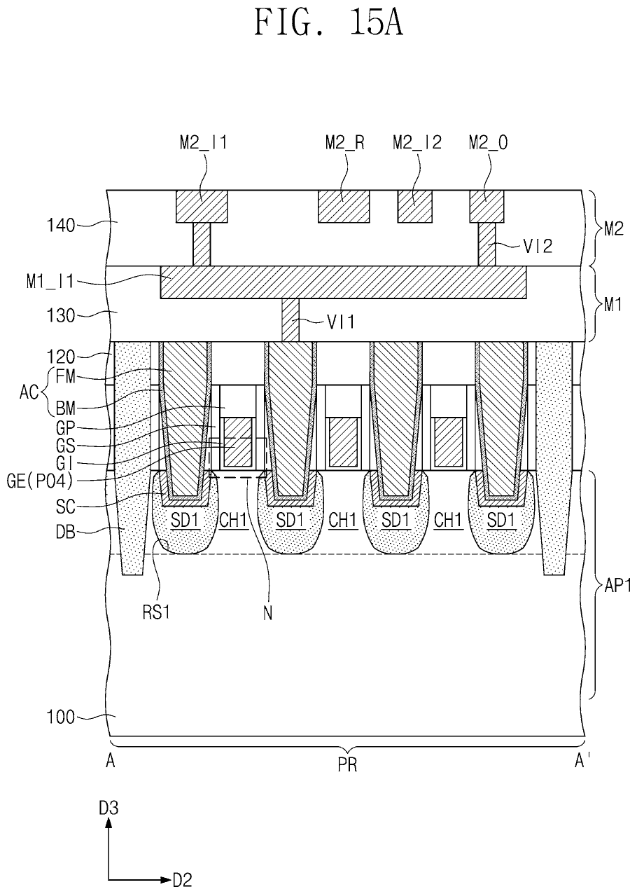

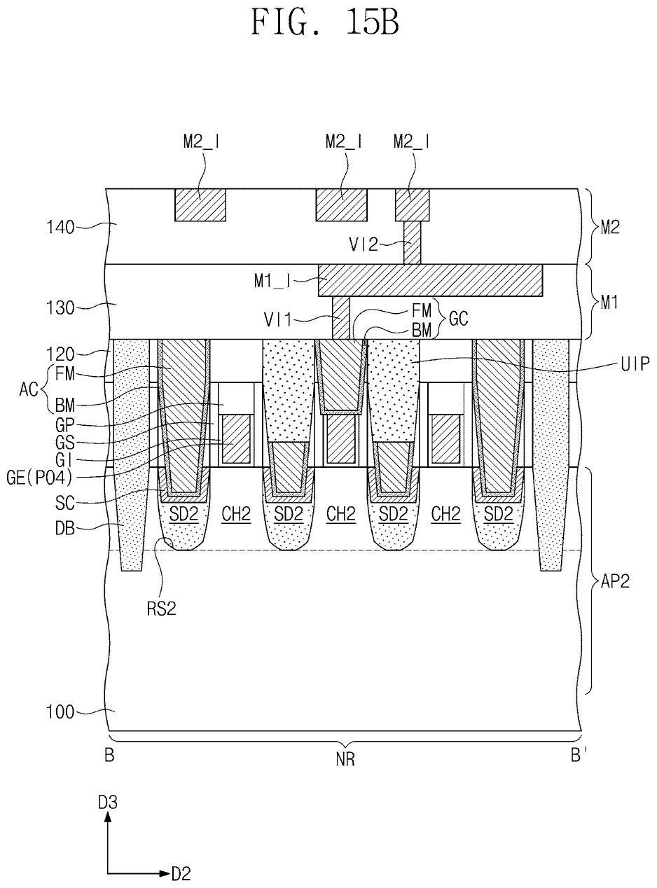

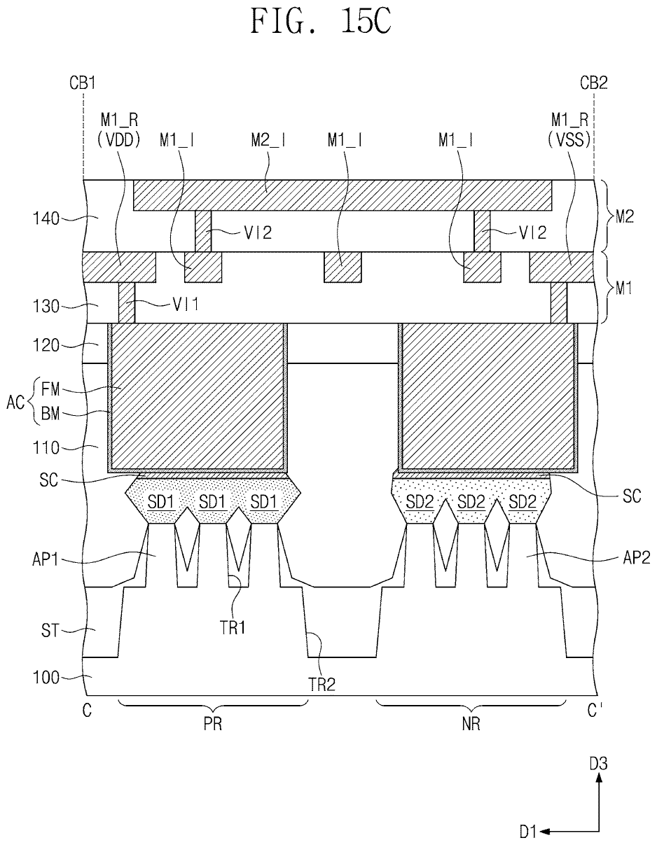

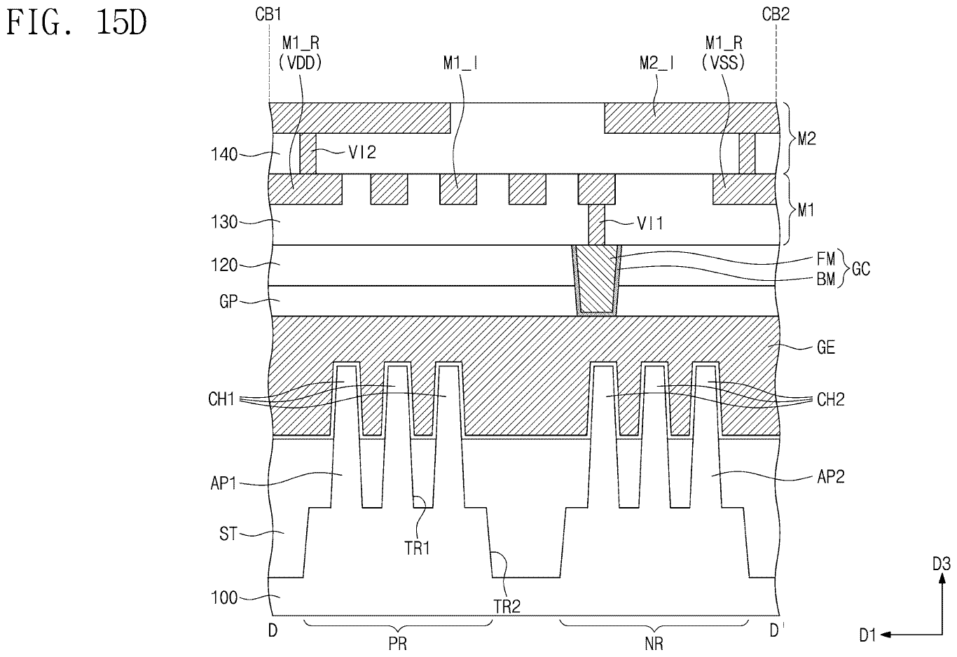

FIGS. 15A, 15B, 15C and 15D are cross-sectional views taken along the lines A-A', B-B', C-C′ and D-D′ of FIG. 1, respectively, to illustrate a semiconductor device according to an exemplary embodiment of the present inventive concept. In the present embodiment, the descriptions to the same technical features and elements as in the above embodiments of FIGS. 1 to 4 will be omitted for the purpose of ease and convenience in explanation, and differences between the present embodiment and the above embodiments of FIGS. 1 to 4 will be mainly described.

Referring to FIGS. 1 and 15A to 15D, a device isolation layer ST may define a first active pattern AP1 and a second active pattern AP2 in an upper portion of the substrate 100. The first active pattern AP1 may be provided on the PMOSFET region PR, and the second active pattern AP2 may be provided on the NMOSFET region NR.

The device isolation layer ST may cover at least a sidewall of a lower portion of each of the first and second active patterns AP1 and AP2. An upper portion of each of the first and second active patterns AP1 and AP2 may protrude beyond the device isolation layer ST (see FIG. 15D).

An upper portion of the first active pattern AP1 may include first source/drain patterns SD1 and a first channel pattern CH1 between the first source/drain patterns SD1. An upper portion of the second active pattern AP2 may include second source/drain patterns SD2 and a second channel pattern CH2 between the second source/drain patterns SD2.

Referring again to FIG. 15D, each of the first and second channel patterns CH1 and CH2 might not include the stacked first to third semiconductor patterns SP1, SP2 and SP3 described above with reference to FIGS. 2A to 2D. Each of the first and second channel patterns CH1 and CH2 may have a semiconductor pillar shape protruding beyond the device isolation layer ST.

A gate electrode GE may be provided on a top surface and both sidewalls of each of the first and second channel patterns CH1 and CH2. In other words, a transistor according to the present embodiment may be a three-dimensional field effect transistor (e.g., a FinFET) in which the gate electrode GE three-dimensionally surrounds a channel.

A first interlayer insulating layer 110 and a second interlayer insulating layer 120 may be provided on the substrate 100. For example, a first interlayer insulating layer 110 and a second interlayer insulating layer 120 may be provided on an entire top surface of the substrate 100. Active contacts AC may penetrate the first and second interlayer insulating layers 110 and 120 and may be connected to the first and second source/drain patterns SD1 and SD2. A gate contact GC may penetrate the second interlayer insulating layer 120 and the gate capping pattern GP and may be connected to the gate electrode GE. The active contacts AC and the gate contact GC may be substantially the same as described above with reference to FIGS. 1 and 2A to 2D.

A third interlayer insulating layer 130 may be provided on the second interlayer insulating layer 120. A fourth interlayer insulating layer 140 may be provided on the third interlayer insulating layer 130. A first metal layer M1 may be provided in the third interlayer insulating layer 130. A second metal layer M2 may be provided in the fourth interlayer insulating layer 140. The first metal layer M1 and the second metal layer M2 may be substantially the same as the first metal layer M1 and the second metal layer M2 described above with reference to FIGS. 1 and 2A to 2D.

An enlarged view of a region ‘N’ of FIG. 15A may be substantially the same as that of FIG. 4. In other words, the gate electrode GE according to the present embodiment may include a channel neighboring part CNP adjacent to the first channel pattern CH1, and a width W5 of the channel neighboring part CNP may become progressively less toward the first channel pattern CH1.

In the semiconductor device according to the exemplary embodiments of the present inventive concept, the gate electrode may have the tapered structure in which its width becomes progressively less toward the channel. Thus, the thickness (or, e.g., width) of the gate spacer may become progressively greater toward the channel. In addition, in an exemplary embodiment of the present inventive concept, the thickness of the gate spacer may remain substantially constant as the channel is approached. A distance between the gate electrode and the source/drain pattern may be increased due to the increase in width of the gate spacer adjacent to the channel and due to the reduction in width of a portion of the gate electrode that is adjacent to the channel. As a result, the exemplary embodiments of the present inventive concept may effectively prevent a process defect in which the source/drain pattern is damaged by the gate electrode and may increase the reliability of the semiconductor device.

In the gate electrode according to an exemplary embodiment of the present inventive concept, the width of the channel neighboring part, of the gate electrode, most adjacent to the channel may be selectively reduced, and the width of the body part, of the gate electrode, may be maintained. Thus, the channel control ability of the gate electrode might not be reduced. In other words, the semiconductor device, according to an exemplary embodiment of the present inventive concept, may have the increased reliability and excellent electrical characteristics.

While the present inventive concept has been particularly shown and described with reference to exemplary embodiments thereof, it will be apparent to those of ordinary skill in the art that various changes in form and detail may be made thereto without departing from the spirit and scope of the present inventive concept.

What is claimed is:

1. A method for manufacturing a semiconductor device, the method comprising:
alternately stacking sacrificial layers and active layers on a substrate;
forming a stack pattern on an active pattern by patterning the sacrificial layers and the active layers;
forming an etch facilitation layer on the stack pattern;
forming a sacrificial semiconductor layer on the etch facilitation layer;
forming a sacrificial pattern by etching the sacrificial semiconductor layer, wherein the etch facilitation layer is patterned together with the sacrificial semiconductor layer in the etching of the sacrificial semiconductor layer;
forming a recess by etching the stack pattern at a side of the sacrificial pattern;
forming a source/drain pattern in the recess;
forming an outer region by removing the sacrificial pattern and the etch facilitation layer;
forming inner regions by removing the sacrificial layers exposed by the outer region; and
forming a gate electrode in the outer region and the inner regions,
wherein an etch rate of the etch facilitation layer is greater than an etch rate of the sacrificial semiconductor layer in the etching of the sacrificial semiconductor layer.

2. The method of claim 1, wherein a width of the sacrificial pattern is greater than a width of the etch facilitation layer disposed under the sacrificial pattern.

3. The method of claim 1, wherein the sacrificial semiconductor layer includes silicon (Si), and
wherein the etch facilitation layer includes silicon-germanium (SiGe).

4. The method of claim 1, wherein the gate electrode includes:
a channel neighboring part formed in a region formed by the removing of the etch facilitation layer; and
a body part formed in a region formed by the removing of the sacrificial pattern,
wherein a width of the body part is greater than a width of the channel neighboring part.

5. The method of claim 1, further comprising:
forming a gate spacer on the etch facilitation layer and the sacrificial pattern,
wherein a thickness of the gate spacer on the etch facilitation layer is greater than a thickness of the gate spacer on the sacrificial pattern.

6. The method of claim 4, wherein the width of the channel neighboring part increases as the body part is approached.

7. The method of claim 4, wherein the width of the channel neighboring part decreases and then increases as the body part is approached.

8. A method for manufacturing a semiconductor device, the method comprising:
alternately stacking sacrificial layers and active layers on a substrate;
forming a stack pattern on an active pattern by patterning the sacrificial layers and the active layers;
forming an etch facilitation layer on the stack pattern;
forming a sacrificial semiconductor layer on the etch facilitation layer;
forming a sacrificial pattern by etching the sacrificial semiconductor layer, wherein the etch facilitation layer is patterned together with the sacrificial semiconductor layer in the etching of the sacrificial semiconductor layer;
forming a recess by etching the stack pattern at a side of the sacrificial pattern;
forming a source/drain pattern in the recess;
forming an outer region by removing the sacrificial pattern and the etch facilitation layer;
forming inner regions by removing the sacrificial layers exposed by the outer region; and
forming a gate electrode in the outer region and the inner regions,
wherein, by etching of the sacrificial semiconductor layer, a width of the etch facilitation layer becomes smaller than a width of the sacrificial pattern.

9. The method of claim 8, wherein the sacrificial semiconductor layer includes silicon (Si), and
wherein the etch facilitation layer includes silicon-germanium (SiGe).

10. The method of claim 8, further comprising:
forming a gate spacer on the etch facilitation layer and the sacrificial pattern,
wherein a thickness of the gate spacer on the etch facilitation layer is greater than a thickness of the gate spacer on the sacrificial pattern.

11. The method of claim 10, wherein the gate electrode includes:
a channel neighboring part formed in a region formed by the removing of the etch facilitation layer; and
a body part formed in a region formed by the removing of the sacrificial pattern,
wherein a width of the body part is greater than a width of the channel neighboring part.

12. The method of claim 11, wherein the channel neighboring part is spaced apart from the source/drain pattern, and wherein the gate spacer is disposed between the channel neighboring part and the source/drain pattern.

13. The method of claim 11, wherein the width of the channel neighboring part increases as the body part is approached.

14. The method of claim 11, wherein the width of the channel neighboring part decreases and then increases as the body part is approached.

15. A method for manufacturing a semiconductor device, the method comprising:
alternately stacking sacrificial layers and active layers on a substrate;
forming a stack pattern on an active pattern by patterning the sacrificial layers and the active layers;
forming an etch facilitation layer on the stack pattern;
forming a sacrificial semiconductor layer on the etch facilitation layer;
forming a sacrificial pattern by etching the sacrificial semiconductor layer;
forming a recess by etching the stack pattern at a side of the sacrificial pattern;
forming a source/drain pattern in the recess;
forming an outer region by removing the sacrificial pattern and the etch facilitation layer;
forming inner regions by removing the sacrificial layers exposed by the outer region; and
forming a gate electrode in the outer region and the inner regions,
wherein the etch facilitation layer is patterned together with the sacrificial semiconductor layer in the etching of the sacrificial semiconductor layer,
wherein the etch facilitation layer includes a first sidewall adjacent to the active layers and extending in a first direction,
wherein the sacrificial pattern includes a third sidewall extending in a second direction intersecting the first direction,
wherein the etch facilitation layer further includes a second sidewall connecting the first sidewall to the third sidewall, and
wherein an angle between the second sidewall and the first direction ranges from about 30° to about 80°.

16. The method of claim 15, wherein the sacrificial semiconductor layer includes silicon (Si), and
wherein the etch facilitation layer includes silicon-germanium (SiGe).

17. The method of claim 15, wherein a width of the sacrificial pattern is greater than a width of the etch facilitation layer.

18. The method of claim 15, wherein the gate electrode includes:
a channel neighboring part formed in a region formed by the removing of the etch facilitation layer; and
a body part formed in a region formed by the removing of the sacrificial pattern,
wherein a width of the body part is greater than a width of the channel neighboring part.

19. The method of claim 18, wherein the width of the channel neighboring part increases as the body part is approached.

20. The method of claim 15, further comprising:
forming a gate spacer on the etch facilitation layer and the sacrificial pattern,
wherein a thickness of the gate spacer on the etch facilitation layer is greater than a thickness of the gate spacer on the sacrificial pattern.
